(19) United States
(12) Patent Application Publication
(10) Pub. No.: US 2025/0110337 A1
(43) Pub. Date: Apr. 3, 2025

(54) LIGHT SOURCE UNIT AND VIDEO DISPLAY APPARATUS

(71) Applicant: NICHIA CORPORATION, Anan-shi (JP)

(72) Inventors: Wataru KITAHARA, Kamiina-gun (JP); Takanori ARUGA, Suwa-gun (JP); Hajime AKIMOTO, Anan-shi (JP)

(73) Assignee: NICHIA CORPORATION, Anan-shi (JP)

(21) Appl. No.: 18/978,166

(22) Filed: Dec. 12, 2024

Related U.S. Application Data
(63) Continuation of application No. PCT/JP2023/021396, filed on Jun. 8, 2023.

(30) Foreign Application Priority Data
Jun. 17, 2022 (JP) 2022-098234

(51) Int. Cl. G02B 27/01; H10H 29/80; H10H 29/856

(52) U.S. Cl. CPC G02B 27/0101; H10H 29/856; H10H 29/872

(57) ABSTRACT

A light source unit includes: a display device configured to emit light that has a substantially Lambertian light distribution and to display a picture; a first prism sheet on which the light emitted from the display device is incident; and an imaging optical system that includes an input element on which light emitted from the first prism sheet is incident and an output element on which light that has passed through the input element is incident, and configured such that light emitted from the output element forms a first image corresponding to the picture. The imaging optical system has a substantially telecentric property on a side of the first image.

### CROSS-REFERENCE TO RELATED APPLICATIONS

The present application is a continuation application of PCT Application No. PCT/JP2023/021396, filed Jun. 8, 2023, which claims priority to JP Application No. 2022-098234, filed Jun. 17, 2022. The contents of these applications are incorporated herein by reference in their entireties.

### BACKGROUND

### 1. Technical Field

Embodiments relate to a light source unit and a video display apparatus.

### 2. Description of Related Art

International Patent Publication No. 2016/208195 discloses a technique in which light emitted from a display device that can display a picture is sequentially reflected by a plurality of mirrors, the light reflected by the last mirror is further reflected by a reflecting member, such as a windshield, toward a user, and a virtual image corresponding to a picture displayed by the display device is visually recognized by the user. Such a device is required to be reduced in size.

### SUMMARY

An embodiment of the present invention has been made in view of the problems described above, and an object thereof is to provide a light source unit and a video display apparatus that can be reduced in size.

A light source unit according to an embodiment of the present invention includes a display device configured to display a picture, a first prism sheet on which light emitted from the display device is incident, and an imaging optical system. The imaging optical system includes an input element on which light emitted from the first prism sheet is incident and an output element on which light that has passed through the input element is incident. Light emitted from the output element forms a first image corresponding to the picture in the imaging optical system. The imaging optical system has a substantially telecentric property on the first image side. The light emitted from the display device has a substantially Lambertian light distribution.

A video display apparatus according to an embodiment of the present invention includes the light source unit, and a reflection unit that is spaced apart from the light source unit and configured to reflect light emitted from the imaging optical system. The first image is formed between the light source unit and the reflection unit.

Embodiments can implement a light source unit and a video display apparatus that can be reduced in size.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is an end view illustrating a video display apparatus according to a first embodiment.

FIG. 2 is a plan view illustrating a display device of a light source unit according to the first embodiment.

FIG. 3A is a perspective view illustrating a first prism sheet of the light source unit according to the first embodiment.

FIG. 3B is an end view illustrating the first prism sheet of the light source unit according to the first embodiment.

FIG. 3C is an end view illustrating the first prism sheet of the light source unit according to the first embodiment.

FIG. 4 is an end view illustrating the display device of the video display apparatus according to the first embodiment.

FIG. 5A is an optical diagram illustrating an action of a second prism in the first embodiment.

FIG. 5B is a view illustrating a pixel of the display device.

FIG. 5C is a view illustrating a pixel enlarged by a first prism.

FIG. 5D is a view illustrating a pixel further enlarged by the second prism.

FIG. 6 is a schematic view illustrating scenery viewed from a viewer in a driver's seat in the first embodiment.

FIG. 7A is a schematic view illustrating the principle of the light source unit according to the first embodiment.

FIG. 7B is a schematic view illustrating the principle of a light source unit according to a reference example.

FIG. 8A is a graph showing light distribution patterns of light emitted from one light-emitting area in the first and eleventh examples and the reference example.

FIG. 8B is a graph showing the uniformity of luminance of a second image in the first to twelfth examples and the reference example.

FIG. 9 is a plan view illustrating a display device in a second embodiment.

FIG. 10A is a plan view illustrating a prism sheet in the second embodiment.

FIG. 10B is an end view taken along line XB-XB illustrated in FIG. 10A.

FIG. 11 is a plan view illustrating the display device and the prism sheet in the second embodiment.

FIG. 12A is a view illustrating a state in which some pixels are lit in the display device.

FIG. 12B is a view illustrating a pixel enlarged by a first prism.

FIG. 13A is an end view illustrating the display device and a first prism sheet of the second embodiment.

FIG. 13B is an optical diagram illustrating the first prism of the present embodiment.

FIG. 13C is an equation representing a relationship among a distance, a prism angle, a refractive index, and a pixel shift amount.

FIG. 13D is a graph showing a relationship between a distance and a prism angle required to obtain a desired pixel shift amount, where a horizontal axis represents the pixel shift amount and a vertical axis represents the prism angle.

FIG. 14A is a view illustrating a distribution of light transmitted through the first prism sheet, and illustrates a case in which the ratio of a prism pitch to a distance is 1.5%.

FIG. 14B is a view illustrating a distribution of light transmitted through the first prism sheet, and illustrates a case in which the ratio of a prism pitch to a distance is 5.0%.

FIG. 15 is a plan view illustrating a first prism sheet of a third embodiment.

FIG. 16A is a view illustrating one pixel in the third embodiment.

FIG. 16B is a view illustrating a pixel enlarged by a first prism.

FIG. 16C is a view illustrating a pixel further enlarged by a second prism.

FIG. 17A is a view illustrating a picture displayed by a display device in the third embodiment.

FIG. 17B is a view illustrating a picture enlarged by the first prism.

FIG. 17C is a view illustrating a picture further enlarged by the second prism.

FIG. 18A is a side view illustrating a display device, a first prism sheet, and a second prism sheet of a light source unit according to a fourth embodiment.

FIG. 18B is a plan view illustrating the first prism sheet of the fourth embodiment.

FIG. 18C is a plan view illustrating the second prism sheet of the fourth embodiment.

FIG. 19 is a side view illustrating a display device, a first prism sheet, a second prism sheet, and a third prism sheet of a light source unit according to a fifth embodiment.

FIG. 20A is a plan view illustrating the first prism sheet of the fifth embodiment.

FIG. 20B is a plan view illustrating the second prism sheet of the fifth embodiment.

FIG. 20C is a plan view illustrating the third prism sheet of the fifth embodiment.

FIG. 21A is a schematic view illustrating an operation of the fifth embodiment.

FIG. 21B is a schematic view illustrating an operation of the fifth embodiment.

FIG. 21C is a schematic view illustrating an operation of the fifth embodiment.

FIG. 21D is a schematic view illustrating an operation of the fifth embodiment.

FIG. 22 is a perspective view illustrating a first prism sheet of a sixth embodiment.

FIG. 23 is an end view illustrating a video display apparatus according to a seventh embodiment.

FIG. 24 is a schematic view illustrating scenery viewed from a viewer in a driver's seat in the seventh embodiment.

FIG. 25 is an end view illustrating a video display apparatus according to an eighth embodiment.

FIG. 26 is an enlarged cross-sectional view illustrating parts of a display device and a reflective polarizing element illustrated in FIG. 25.

FIG. 27 is a side view illustrating a light source unit according to a ninth embodiment.

FIG. 28 is a side view illustrating a light source unit according to a modified example of the ninth embodiment.

### DETAILED DESCRIPTION

### Description of Embodiments

Hereinafter, embodiments and modified examples thereof are described with reference to the drawings. Note that the drawings are schematic or conceptual and are appropriately emphasized or simplified. For example, a relationship between a thickness and a width of each portion, a ratio of sizes between portions, and the like are not necessarily the same as actual ones. In addition, even in the case of representing the same portion, dimensions or ratios may be represented differently depending on the drawings. Moreover, in the present specification and the drawings, elements similar to those described with reference to the drawings already mentioned are denoted by the same reference characters, and detailed descriptions thereof are omitted as appropriate.

### First Embodiment

First, a first embodiment is described.

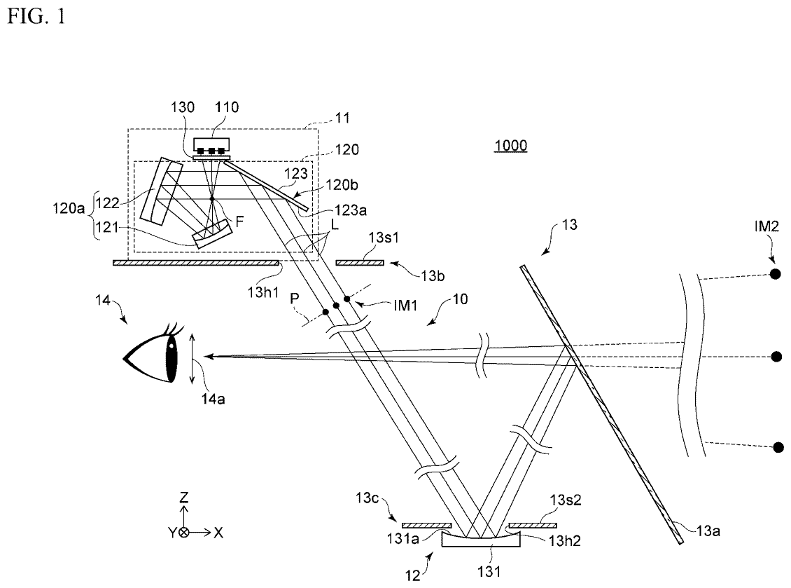

FIG. 1 is an end view illustrating a video display apparatus according to the present embodiment.

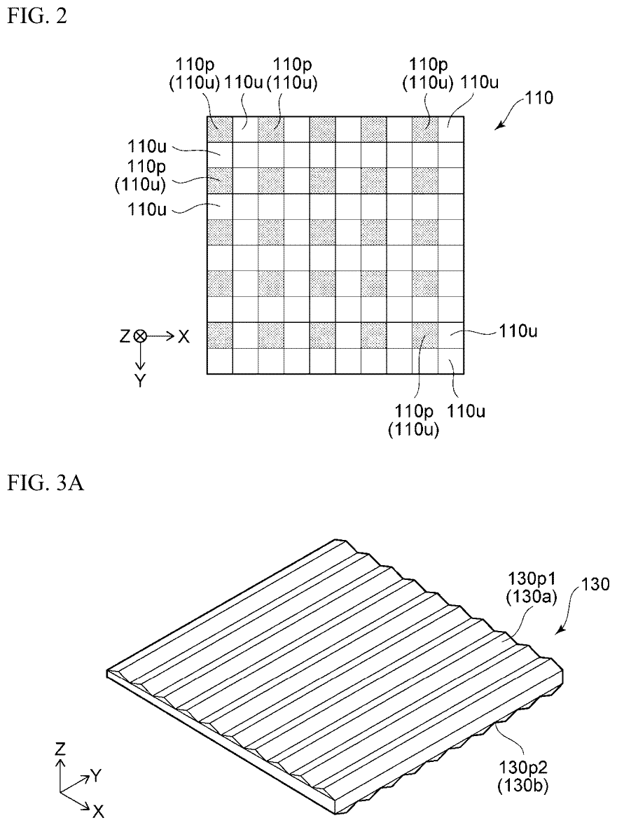

FIG. 2 is a plan view illustrating a display device of a light source unit according to the present embodiment.

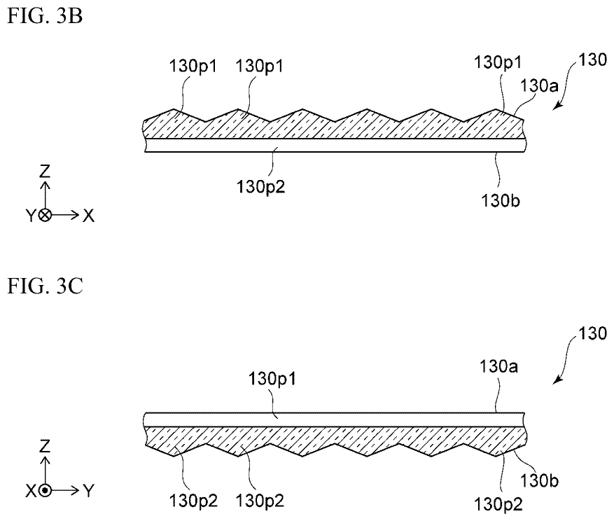

FIG. 3A is a perspective view illustrating a first prism sheet of the light source unit according to the present embodiment.

FIGS. 3B and 3C are end views illustrating the first prism sheet of the light source unit according to the present embodiment.

As illustrated in FIG. 1, a video display apparatus 10 according to the present embodiment includes a light source unit 11 and a reflection unit 12. The light source unit 11 includes a display device 110, an imaging optical system 120, and a first prism sheet 130. The display device 110 includes a plurality of pixels and can display a picture. Light emitted from the display device 110 is incident on the first prism sheet 130. The imaging optical system 120 receives light emitted from the first prism sheet 130 and forms a first image IM1 corresponding to the picture displayed by the display device 110. The first image IM is a real image and is an intermediate image. The reflection unit 12 is spaced apart from the light source unit 11 and reflects light emitted from the imaging optical system 120.

The video display apparatus 10 is mounted on, for example, an automobile 1000 and constitutes a head-up display (HUD). The automobile 1000 includes a vehicle 13 and the video display apparatus 10 fixed to the vehicle 13. A viewer 14 is a passenger of the automobile 1000, for example, a driver.

The display device 110 of the light source unit 11 displays a picture to be visually recognized by the viewer 14 via the HUD. The first prism sheet 130 refracts light emitted from each pixel of the display device 110 to enlarge a region the light emitted from the pixel reaches. This mechanism is described below. The imaging optical system 120 outputs the light emitted from the first prism sheet 130 to the reflection unit 12 and forms the first image IM between the light source unit 11 and the reflection unit 12. The reflection unit 12 reflects the light emitted from the light source unit 11 toward a front windshield 13a of the vehicle 13. The front windshield 13a includes, for example, glass.

The front windshield 13a reflects, on its inner surface, the light having reached from the reflection unit 12, and causes the light to enter an eye box 14a of the viewer 14. Thus, the viewer 14 can visually recognize a second image IM2 corresponding to the picture displayed by the display device 110 on the opposite side of the front windshield 13a. The second image IM2 is a virtual image larger than the first image MI1. The “eye box” refers to a range in which a virtual image can be visually recognized in a space in front of the eyes of a viewer.

For ease of explanation, the arrangement and configuration of portions are described using an XYZ orthogonal coordinate system in the following description. In the present embodiment, the front-rear direction of the vehicle 13 is referred to as an “X direction,” the left-right direction of the vehicle 13 is referred to as a “Y direction,” and the up-down direction of the vehicle 13 is referred to as a “Z direction.” An XY plane is a horizontal plane of the vehicle 13. In the X direction, the direction (forward) of an arrow is also referred to as a “+X direction,” and the opposite direction (rearward) thereof is also referred to as a “−X direction.” In the Y direction, the direction (leftward) of an arrow is referred to as a “+Y direction,” and the opposite direction (rightward) thereof is referred to as a “−Y direction.” In the Z directions, the direction (upward) of an arrow is referred to as a “+Z direction,” and the opposite direction (downward) thereof is referred to as a “−Z direction.”

In FIG. 1, the position where the first image IM1 is formed is indicated by a circular mark. As in the case of the first image IM1, the position where the second image IM2 is formed is also indicated by a circular mark. On the other hand, a position from which a principal ray L to reach each mark of the first image IM1 is emitted in the display device 110 is indicated by a square mark. In this way, for ease of explanation, the emission position of each principal ray L on the display device 110 is indicated by a mark different from those for the imaging position of the first image IM1 and the imaging position of the second image IM2, but the picture displayed on the display device 110, the first image IM1, and the second image IM2 are substantially in a geometric similarity relationship.

As illustrated in FIG. 2, in the display device 110, unit regions 110u along a third direction and a fourth direction are arranged in a matrix, and a pixel 110p is disposed in every other unit region 110u in the third direction and the fourth direction. Thus, one pixel 110p is arranged for every four unit regions 110u of two rows and two columns. In this way, in the display device 110, a plurality of pixels 110p are arranged in a staggered manner along the third direction and the fourth direction.

The fourth direction intersects with, for example, is orthogonal to, the third direction. For example, the third direction is a horizontal direction of the picture, and the fourth direction is a vertical direction of the picture. In the present embodiment, the third direction is the X direction and the fourth direction is the Y direction. The light emitted from the display device 110 has a substantially Lambertian light distribution. The specific configuration of the display device 110 and the Lambertian light distribution are described in detail below.

As illustrated in FIGS. 3A to 3C, the first prism sheet 130 has a first surface 130a on which the light emitted from the display device 110 is incident and a second surface 130b on the opposite side of the first surface 130a. The second surface 130b emits light toward the imaging optical system 120. On the first surface 130a of the first prism sheet 130, stripe-shaped first prisms 130p1 extending in the fourth direction (Y direction) are formed, and on the second surface 130b, stripe-shaped second prisms 130p2 extending in the third direction (X direction) are formed.

When viewed from the −Z direction, the first prism sheet 130 has a size equal to or larger than that of the display device 110, and covers the display device 110. The arrangement cycle of the first prisms 130p1 in the X direction is shorter than the arrangement cycle of the unit regions 110u of the display device 110 in the X direction. Similarly, the arrangement cycle of the second prisms 130p2 in the Y direction is shorter than the arrangement cycle of the unit regions 110u in the Y direction. Thus, light emitted from each pixel 110p of the display device 110 is always incident on one or more first prisms 130p1 and one or more second prisms 130p2.

Configurations other than those described above in the video display apparatus 10 are described below.

First, the display device 110 is described.

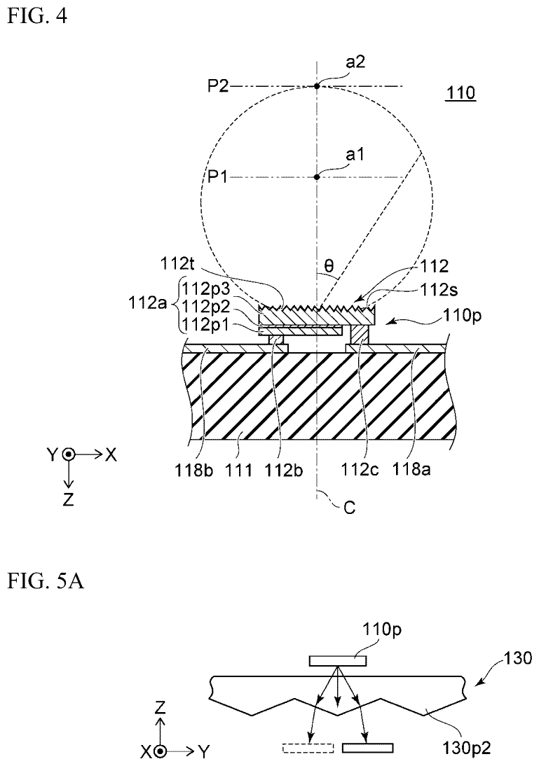

FIG. 4 is an end view illustrating the display device of the video display apparatus according to the present embodiment.

The display device 110 of the light source unit 11 is an LED display. In the display device 110, a plurality of LED elements 112 are arranged in a staggered manner. One or more LED elements 112 are arranged in each pixel 110p of the display device 110.

As illustrated in FIG. 4, in the display device 110, each LED element 112 is mounted face-down on a substrate 111. However, each LED element may be mounted face-up on the substrate. Each LED element 112 includes a semiconductor layered body 112a, an anode electrode 112b, and a cathode electrode 112c. An insulating material such as a resin or glass is used for the substrate 111. A silicon semiconductor chip for driving each LED element 112 can also be used for the substrate 111.

The semiconductor layered body 112a includes a p-type semiconductor layer 112p1, an active layer 112p2 disposed on the p-type semiconductor layer 112p1, and an n-type semiconductor layer 112p3 disposed on the active layer 112p2. For the semiconductor layered body 112a, for example, a gallium nitride-based compound semiconductor expressed as In_{X}Al_{Y}Ga_{1-X-Y}N (0≤X, 0≤Y, X+Y<1) is used. Light emitted by the LED element 112 is visible light in the present embodiment.

The anode electrode 112b is electrically connected to the p-type semiconductor layer 112p1. The anode electrode 112b is electrically connected to a wiring line 118b. The cathode electrode 112c is electrically connected to the n-type semiconductor layer 112p3. The cathode electrode 112c is electrically connected to another wiring line 118a. For each of the electrodes 112b and 112c, for example, a metal material can be used.

In the present embodiment, a plurality of recessed portions 112t are provided on a light exit surface 112s of each of the LED elements 112. In the present specification, the “light exit surface of the LED element” means a surface from which light to be incident on an imaging optical system 120 is mainly emitted among the surfaces of the LED element. In the present embodiment, the surface of the n-type semiconductor layer 112p3 located on a side opposite to a surface facing the active layer 112p2 corresponds to the light exit surface 112s.

Hereinafter, an optical axis of light emitted from each pixel 110p is simply referred to as “optical axis C.” The optical axis C is, for example, a straight line connecting a point a1 and a point a2, the point a1 having a maximum luminance in a range irradiated with light from one pixel 110p on a first plane P1 parallel to the XY plane on which a plurality of pixels 110p are arranged and located on the light exit side of the display device 110, the point a2 having a maximum luminance in a range irradiated with the light from the pixel 110p on a second plane P2 parallel to the XY plane and separated from the first plane P1. When there are a plurality of points at which the luminance is maximum, for example, the center point of these points may be set as the point at which the luminance is maximum. From the viewpoint of productivity, the optical axis C is desirably parallel to a Z-axis.

In this way, because the plurality of recessed portions 112t are provided in the light exit surface 112s of each LED element 112, light emitted from the LED element 112, that is, light emitted from each pixel 110p has a substantially Lambertian light distribution as indicated by a broken line in FIG. 4. Here, “the light emitted from each pixel has a substantially Lambertian light distribution” means that the light has a light distribution pattern in which the luminous intensity of each pixel in a direction at an angle θ with respect to the optical axis C can be approximated by cosⁿθ times the luminous intensity on the optical axis C, where n is a value greater than 0. Here, n is preferably 11 or less, more preferably 1. Note that although there are many planes including the optical axis C of light emitted from one pixel 110p, the light distribution pattern of the light emitted from the pixel 110p in each plane is a substantially Lambertian light distribution and the numerical value of n is also approximately the same.

The imaging optical system 120 is described in detail below.

As illustrated in FIG. 1, the imaging optical system 120 of the light source unit 11 is an optical system including all optical elements necessary for forming the first image IM1 at a predetermined position. In the present embodiment, the imaging optical system 120 includes an input element 121 on which light emitted from the second surface 130b of the first prism sheet 130 is incident, an intermediate element 122 on which light reflected by the input element 121 is incident, and an output element 123 on which light reflected by the intermediate element 122 is incident. Light emitted from the output element 123 forms the first image IM1. The intermediate element 122 need not be provided as long as light that has passed through the input element 121 is incident on the output element 123.

The imaging optical system 120 has a substantially telecentric property on the first image IM1 side. Here, “the imaging optical system 120 has a substantially telecentric property on the first image IM1 side” means that as illustrated in FIG. 1, a plurality of principal rays L emitted from mutually different positions in the display device 110 to reach the first image IM1 via the imaging optical system 120 are substantially parallel to each other before and after the first image IM1. The different positions are, for example, different pixels 110p of the display device 110. “The plurality of principal rays L are substantially parallel to each other” means that the principal rays L are substantially parallel to each other within a practical range in which an error due to manufacturing accuracy, assembly accuracy, or the like of the components of the light source unit 11 is allowed. When “the plurality of principal rays L are substantially parallel to each other,” for example, an angle between the principal rays L is 10° or less.

When the imaging optical system 120 has a substantially telecentric property on the first image IM1 side, the plurality of principal rays L intersect with each other before entering the input element 121. Hereinafter, a point at which the plurality of principal rays L intersect with each other is referred to as a “focal point F.” Therefore, whether the imaging optical system 120 has a substantially telecentric property on the first image IM side can be confirmed by, for example, the following method using the reversibility of light-path. First, a light source that can emit parallel light, such as a laser light source, is disposed near the position where the first image IM1 is formed. The output element 123 of the imaging optical system 120 is irradiated with light emitted from the light source. The light emitted from the light source to pass through the output element 123 enters the input element 121. Subsequently, when a point where light emitted from the input element 121 is condensed, that is, the focal point F is present before the light reaches the display device 110A, it can be determined that the imaging optical system 120 has a substantially telecentric property on the first image IM1 side.

Because the imaging optical system 120 has a substantially telecentric property on the first image IM side, light that has passed through the focal point F and the vicinity thereof among the light emitted from each pixel of the display device 110 is mainly incident on the imaging optical system 120. Each optical element included in the imaging optical system 120 is described below.

The input element 121 is located on the −Z side of the display device 110 and faces the display device 110. The input element 121 is a mirror having a concave mirror surface 121a. The input element 121 reflects the light emitted from the display device 110.

The intermediate element 122 is located on the −X side with respect to the display device 110 and the input element 121 and faces the input element 121. The intermediate element 122 is a mirror having a concave mirror surface 122a. The intermediate element 122 further reflects the light reflected by the input element 121.

The input element 121 and the intermediate element 122 constitute a bend portion 120a that bends the plurality of principal rays L such that the plurality of principal rays L emitted from mutually different positions of the display device 110 are substantially parallel to each other. In the present embodiment, the mirror surfaces 121a and 122a are biconic surfaces. However, the mirror surface may be a part of a spherical surface or may be a free-form surface.

The output element 123 is located on the +X side with respect to the display device 110 and the input element 121, and faces the intermediate element 122. The output element 123 is a mirror having a flat mirror surface 123a. The output element 123 reflects the light that has passed through the inputting device 121 and the intermediate element 122 toward the formation position of the first image IM1. Specifically, the plurality of principal rays L made to be substantially parallel to each other by the bend portion 120a are incident on the output element 123. The mirror surface 123a is inclined with respect to the XY plane being a horizontal plane of the vehicle 13 so as to be directed in the +X direction as it is directed in the −Z direction. Thus, the output element 123 reflects the light reflected by the intermediate element 122 in a direction inclined with respect to the Z direction such that the light is directed in the +X direction as the light is directed in the −Z direction. As illustrated in FIG. 1, the output element 123 constitutes a direction changing portion 120b that changes the direction of the plurality of principal rays L such that the plurality of principal rays L made to be substantially parallel to each other by the bend portion 120a are directed to a formation position P of the first image IM1.

In the present embodiment, an optical path between the input element 121 and the intermediate element 122 extends in a direction intersecting with the XY plane. An optical path between the intermediate element 122 and the output element 123 extends in a direction along the XY plane. Because a part of the optical paths in the imaging optical system 120 extends in the direction intersecting with the XY plane, the light source unit 11 can be reduced in size to some extent in the direction along the XY plane. In addition, because another part of the optical paths in the imaging optical system 120 extends in the direction along the XY plane, the light source unit 11 can be reduced in size to some extent in the Z direction.

In addition, an optical path between the display device 110 and the input element 121 intersects with the optical path between the intermediate element 122 and the output element 123. By making the optical paths intersect with each other in the light source unit 11 in this way, the light source unit 11 can be reduced in size.

However, the optical paths in the light source unit are not limited to those described above. For example, all the optical paths in the imaging optical system may extend in the direction along the XY plane or may extend in the direction intersecting with the XY plane. The optical paths in the light source unit need not intersect with each other.

The input element 121, the intermediate element 122, and the output element 123 may each be constituted of a body member made of glass, a resin material, or the like, and a reflective film such as a metal film or a dielectric multilayer film that is provided on the surface of the body member and forms a corresponding one of the mirror surfaces 121a, 122a, and 123a. Each of the input element 121, the intermediate element 122, and the output element 123 may be entirely made of a metal material.

As illustrated in FIG. 1, in the present embodiment, the light source unit 11 is provided on a ceiling portion 13b of the vehicle 13. The light source unit 11 is disposed, for example, on an inner side of a wall 13s1 exposed to the interior of the vehicle in the ceiling portion 13b. The wall 13s1 is provided with a through hole 13h1 through which light emitted from the output element 123 of the light source unit 11 can pass. The light emitted from the output element 123 passes through the through hole 13h1 and is emitted to a space between the viewer 14 and the front windshield 13a. The light source unit may be attached to a ceiling surface. The through hole 13h1 may be provided with a cover that is transparent or translucent and has a small haze value. The haze value is preferably 50% or less, more preferably 20% or less.

Although the imaging optical system 120 has been described above, the configuration and position of the imaging optical system are not limited to those described above as long as the imaging optical system has a substantially telecentric property on the first image side. For example, the number of optical elements constituting the direction changing portion may be two or more.

The reflection unit 12 is described below.

As illustrated in FIG. 1, in the present embodiment, the reflection unit 12 includes a mirror 131 having a concave mirror surface 131a. The mirror 131 faces the front windshield 13a. The mirror 131 reflects the light emitted from the output element 123 and thus the front windshield 13a is irradiated with the light. The mirror 131 may include a body member made of glass, a resin material, or the like, and a reflective film such as a metal film or a dielectric multilayer film that is provided on the surface of the body member and forms the mirror surface 131a. The mirror 131 may be entirely made of a metal material. In an example, the mirror surface 131a is a biconic surface. However, the mirror surface may be a part of a spherical surface or may be a free-form surface.

The light emitted to the front windshield 13a is reflected by an inner surface of the front windshield 13a and enters the eye box 14a of the viewer 14. Thus, the viewer 14 visually recognizes the second image IM2 corresponding to the picture displayed on the display device 110 on the opposite side of the front windshield 13a.

In the present embodiment, the reflection unit 12 is provided in a dashboard portion 13c of the vehicle 13. The reflection unit 12 is disposed, for example, on an inner side of a wall 13s2 exposed to the interior of the vehicle 13 in the dashboard portion 13c. The wall 13s2 is provided with a through hole 13h2 through which light emitted from the output element 123 of the light source unit 11 can pass. The light emitted from the output element 123 passes through the through hole 13h1 to form the first image IM1, and then is emitted to the reflection unit 12 by passing through the through hole 13h2. However, the reflection unit may be attached to an upper surface of the dashboard portion. In addition, the reflection unit may be disposed in the ceiling portion, and the light source unit may be disposed in the dashboard portion.

The path of light from the inner surface of the front windshield 13a toward the eye box 14a is substantially horizontal, and is completely horizontal or slightly inclined such that the eye box 14a side is higher. That is, this path is substantially parallel to the XY plane. In the present embodiment, the light source unit 11 is disposed on an upper side (+Z direction) and the reflection unit 12 is disposed on a lower side (−Z direction), with respect to the XY plane including the path of the light. That is, the light source unit 11 and the reflection unit 12 are spaced apart from each other with the XY plane interposed therebetween.

Although the reflection unit 12 has been described above, the configuration and the position of the reflection unit are not limited to those described above. For example, the number of optical elements such as mirrors constituting the reflection unit may be two or more. The reflection unit 12 needs to be disposed such that, for example, sunlight emitted from the outside of the vehicle through the front windshield 13a is not reflected toward the eye box 14a.

The operation of the video display apparatus 10 according to the present embodiment is described below.

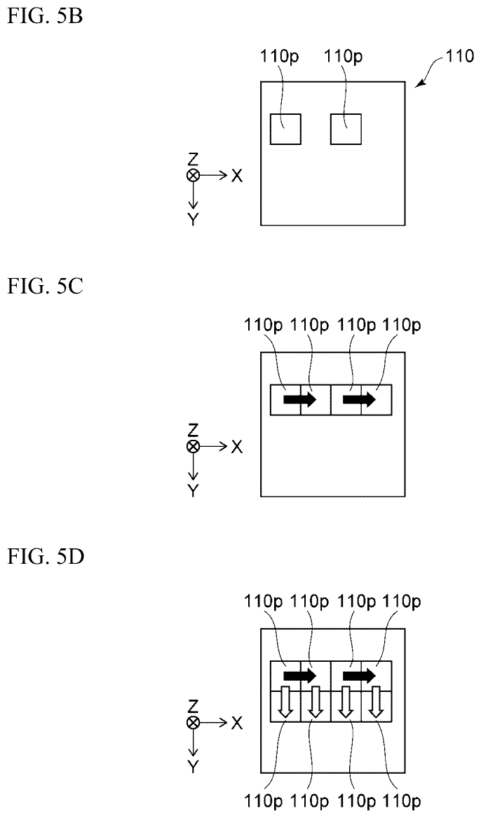

FIG. 5A is an optical diagram illustrating the action of the second prism 130p2 in the present embodiment.

FIG. 5B is a view illustrating the pixel 110p of the display device 110.

FIG. 5C is a view illustrating a pixel enlarged by the first prism 130p1.

FIG. 5D is a view illustrating a pixel further enlarged by the second prism 130p2.

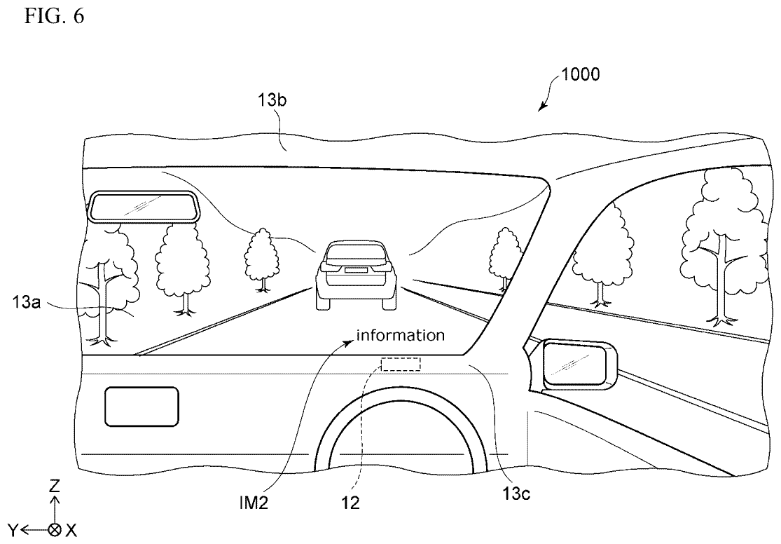

FIG. 6 is a schematic view illustrating a scene viewed from a viewer in a driver's seat in the present embodiment.

As illustrated in FIG. 5A, light emitted from the pixel 110p of the display device 110 is separated in the Y direction by the second prism 130p2 of the first prism sheet 130, and a region the light reaches spreads in the Y direction. Similarly, the light emitted from the pixel 110p is separated in the X direction by the first prism 130p1, and a region the light reaches spreads in the X direction. Consequently, when the light emitted from the pixel 110p is transmitted through the first prism sheet 130, a region the light reaches spreads in the X direction and the Y direction.

FIG. 5B illustrates two pixels 110p of the display device 110. As described above, the pixels 110p are spaced apart from each other.

When light emitted from the two pixels 110p is incident on the first prism 130p1 of the first prism sheet 130, the light is separated in the X direction as illustrated in FIG. 5C. Thus, when viewed from the viewer 14 side, each pixel 110p appears to be separated into two pixels 110p along the X direction. Hereinafter, in the present specification, a state in which light emitted from one pixel is separated by a prism and the pixel appears to be separated when viewed from the viewer 14 side is referred to as “pixel separation.”

When the light spread by the first prism 130p1 is incident on the second prism 130p2, the light is separated in the Y direction as illustrated in FIG. 5D. Thus, when viewed from the viewer 14 side, each pixel 110p illustrated in FIG. 5C appears to be separated into two pixels 110p along the Y direction. Consequently, the light emitted from the pixel 110p spreads in the X direction and the Y direction due to the action of the first prism 130p1 and the second prism 130p2, and the area of a region the light reaches becomes, for example, four times the area of the pixel 110p.

In this way, the rays L are emitted from the first prism sheet 130. At this time, although the region the light emitted from each pixel 110p reaches is enlarged in the X direction and the Y direction, the positional relationship between the pixels 110p does not change, and thus a picture displayed by the display device 110 is maintained as is. On the basis of this picture, the imaging optical system 120 of the light source unit 11 forms the first image IM1 being a real image at the position P. Subsequently, the light having formed the first image IM1 is reflected by the reflection unit 12 and the front windshield 13a, and enters the eye box 14a of the viewer 14.

Thus, as illustrated in FIG. 6, the viewer 14 visually recognizes the second image IM2 being a virtual image on the opposite side of the front windshield 13a. Although the second image IM2 is represented by a character string “information” in FIG. 6, the second image IM2 is not limited to a character string and may be a graphic or the like.

Subsequently, an effect of the present embodiment is described.

In the present embodiment, as illustrated in FIG. 2, in the display device 110, the pixel 110p is disposed in every other unit region 110u in the X direction and the Y direction. Thus, the size of the display device 110 can be increased and the size of a picture displayed by the display device 110 can be increased without increasing the number of pixels 110p. This can reduce the enlargement ratio of the picture, that is, the value of the ratio of the size of the second image IM2 to the size of the picture displayed by the display device 110, and reduce the size of the imaging optical system 120. As a result, although the display device 110 is increased in size, the imaging optical system 120 is reduced in size, so that the light source unit 11 as a whole can be reduced in size. Consequently, the video display apparatus 10 can also be reduced in size.

In addition, by enlarging light emitted from each pixel 110p of the display device 110 by the first prism sheet 130, the separation between the pixels 110p of the display device 110 is less likely to be visually recognized in the second image IM2. As a result, even though the pixels 110p are spaced apart from each other, the quality of the second image IM2 can be made equivalent to that when the pixels 110p are not spaced apart from each other. Although light emitted from a pixel can be enlarged by using a diffusion sheet or the like, the use of the prism sheet as in the present embodiment allows emitted light to be enlarged while suppressing a decrease in luminance.

Note that it is also conceivable that the pixels 110p in the display device 110 having a large size are arranged without gaps, but in this case, the number of the LED elements 112 increases, and the cost increases.

In the present embodiment, in the display device 110, the pixel 110p is disposed in every other unit region 110u in the X direction and the Y direction and the first prism sheet 130 doubles a region light emitted from the pixel 110p reaches in the X direction and the Y direction; however, no such limitation is intended. For example, in the display device 110, the pixel 110p may be disposed in every other unit region 110u only in the X direction, the pixel 110p may be disposed in all the unit regions 110u continuously arranged in the Y direction, only the first prism 130p1 may be provided in the first prism sheet 130, and the second prism 130p2 need not be provided. Similarly, in the display device 110, the pixel 110p may be disposed in every other unit region 110u only in the Y direction, the pixel 110p may be disposed in all the unit regions 110u continuously arranged in the X direction, only the second prism 130p2 may be provided in the first prism sheet 130, and the first prism 130p1 need not be provided. In addition, one pixel 110p may be disposed in every two or more unit regions 110u in the X direction and the Y direction, and the first prism sheet 130 may increase a region, which light emitted from the pixel 110p reaches, by three times or more in the X direction and the Y direction.

Although the first prism 130p1 and the second prism 130p2 are provided in the single first prism sheet 130 in the present embodiment, no such limitation is intended and the first prism 130p1 and the second prism 130p2 may be separately provided in two prism sheets.

In addition, in the present embodiment, the imaging optical system 120 has a substantially telecentric property on the first image IM1 side, so that the light source unit 11 and the video display apparatus 10 can be reduced in size while displaying a high-quality video. This effect is described in detail below.

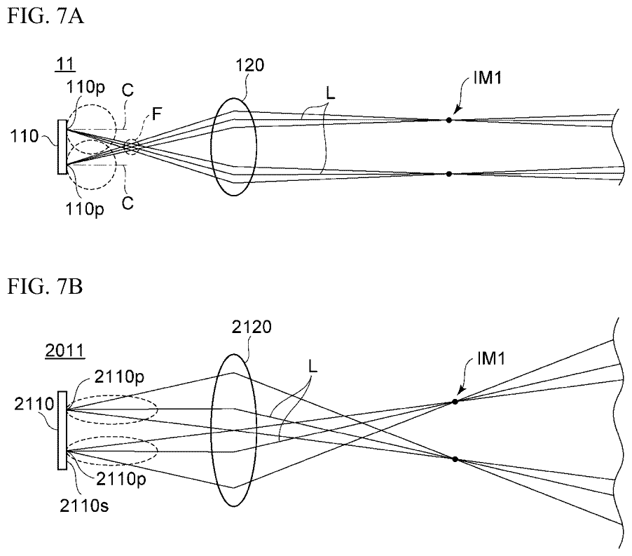

FIG. 7A is a schematic view illustrating the principle of the light source unit according to the present embodiment.

FIG. 7B is a schematic view illustrating the principle of a light source unit according to a reference example.

In FIG. 7A, light distribution patterns of light emitted from two pixels 110p among the plurality of pixels 110p of the display device 110 in the present embodiment are indicated by broken lines. Similarly, in FIG. 7B, light distribution patterns of light emitted from two pixels 2110p among a plurality of pixels 2110p of a display device 2110 in the reference example are indicated by broken lines. In addition, the imaging optical systems 120 and 2120 are illustrated in a simplified manner in FIGS. 7A and 7B.

As illustrated in FIG. 7B, in a light source unit 2011 according to the reference example, the display device 2110 is a liquid crystal display (LCD) including the plurality of pixels 2110p. As indicated by the broken lines in FIG. 7B, light emitted from each pixel 2110p is mainly distributed in a normal direction of a light exit surface 2110s. Although there are many planes including the optical axis of the light emitted from one pixel 2110p, in the display device 2110 being the LCD, the light distribution patterns of the light emitted from one pixel 2110p in the planes are different from each other. In one plane of the plurality of planes, the light emitted from each pixel 2110p has a light distribution pattern in which the luminous intensity in a direction at an angle θ with respect to the optical axis is approximated by cos²⁰θ times the luminous intensity on the optical axis.

In such a display device 2110, even light emitted from the same position of the display device 2110 changes in luminous intensity and chromaticity depending on the viewing angle of a viewer. Consequently, if the imaging optical system 2120 captures light emitted from each pixel 2110p in a direction other than the normal direction and the luminance of the light emitted from all the pixels 2110p is made uniform, variations in luminance and chromaticity occur in the first image IM1. That is, the quality of the first image IM1 is degraded. Consequently, to prevent the quality of the first image IM from being degraded, the light emitted from each pixel 2110p of the display device 2110 needs to be captured along the normal direction. As a result, the imaging optical system 2120 is increased in size.

On the other hand, in the light source unit 11 according to the present embodiment, the imaging optical system 120 has a substantially telecentric property on the first image IM1 side, and light emitted from the display device 110 has a substantially Lambertian light distribution. Therefore, the quality of the first image IM can be improved while reducing the size of the light source unit 11. Specifically, the display device 110 is an LED display including the plurality of LED elements 112, and the LED element 112 is provided with the recessed portions 112t, so that light emitted from each LED element 112 has a substantially Lambertian light distribution. Therefore, the dependence of the luminous intensity and chromaticity of light emitted from each pixel 110p of the display device 110 on an angle is lower than the dependence of the luminous intensity and chromaticity of light emitted from each pixel 2110p of the display device 2110 on an angle in the reference example. In particular, as the light distribution becomes closer to a strict Lambertian light distribution, that is, as n of cosⁿθ being an approximate expression of the light distribution pattern becomes closer to 1, the luminous intensities and chromaticities of the light emitted from the pixels 110p of the display device 110 become substantially uniform regardless of an angle. Therefore, as illustrated in FIG. 7A, even though the imaging optical system 120 captures light that has passed through the focal point F, that is, captures light from a direction other than the normal direction, variations in the luminance and chromaticity of the first image IM1 can be suppressed and the quality of the first image IM1 can be improved.

In addition, because the imaging optical system 120 mainly forms the first image IM1 with light that has passed through the focal point F, an increase in the light diameter of light incident on the imaging optical system 120 can be suppressed. Thus, the input element 121 can be reduced in size. Moreover, the plurality of principal rays L emitted from the output element 123 are substantially parallel to each other. The fact that the plurality of principal rays L emitted from the output element 123 are substantially parallel to each other means that the size of the range irradiated with light that contributes to image formation in the output element 123 is substantially the same as the size of the first image IM1. Therefore, the output element 123 of the imaging optical system 120 can also be reduced in size. From the above, the light source unit 11 that is small and can form the first image IM1 with high quality can be provided.

The video display apparatus 10 according to the present embodiment includes the light source unit 11, and the reflection unit 12 that is spaced apart from the light source unit 11 and reflects light emitted from the imaging optical system 120. The first image IM1 is formed between the light source unit 11 and the reflection unit 12. In such a case, light emitted from a particular point of the display device 110 passes through the output element 123, and then is condensed at the formation position of the first image IM1. On the other hand, when the first image IM1 is not formed between the light source unit 11 and the reflection unit 12, the light diameter of light emitted from a particular point of the display device 110 gradually increases from the input element 121 toward the reflection unit 12. Consequently, in the present embodiment, the range of the output element 123 irradiated with the light emitted from a particular point of the display device 110 can be made smaller than when the first image IM1 is not formed. Therefore, the output element 123 can be reduced in size.

In addition, because the light source unit 11 according to the present embodiment is small, when the light source unit 11 is mounted on the vehicle 13 and used as a head-up display, the light source unit 11 can be easily disposed in a limited space in the vehicle 13.

In addition, the imaging optical system 120 in the present embodiment includes the bend portion 120a and the direction changing portion 120b. In this way, in the imaging optical system 120, a portion having a function of making the principal rays L parallel to each other and a portion for forming the first image IM1 at a desired position are separated from each other, so that the design of the imaging optical system 120 is facilitated.

A part of the optical path in the imaging optical system 120 extends in a direction intersecting with the XY plane. Therefore, the imaging optical system 120 can be reduced in size to some extent in the direction along the XY plane. Another part of the optical path in the imaging optical system 120 extends in a direction along the XY plane. Therefore, the imaging optical system 120 can be reduced in size to some extent in the Z direction.

### EXAMPLES

Light source units according to examples and a reference example are described below.

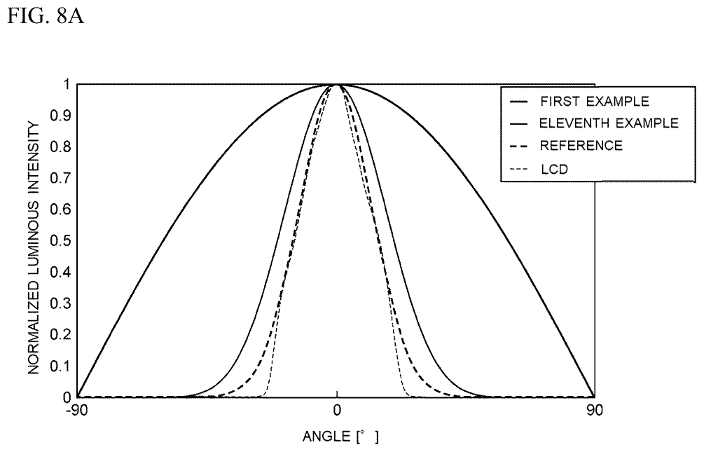

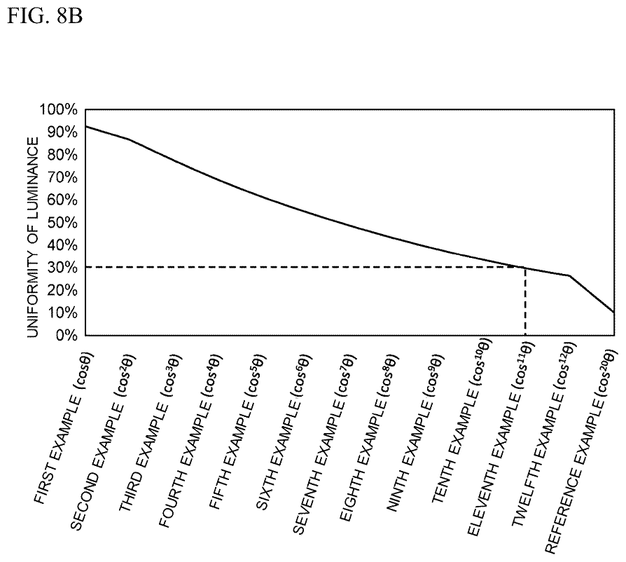

FIG. 8A is a graph showing light distribution patterns of light emitted from one light-emitting area in first and eleventh examples and a reference example.

FIG. 8B is a graph showing the uniformity of luminance of a second image in the first to twelfth examples and the reference example.

Setting was performed on the simulation software such that video display apparatuses according to the first to twelfth examples and the reference example each include a light source unit and a reflection unit and the light source unit includes a plurality of light-emitting areas arranged in a matrix and an imaging optical system. Each light-emitting area corresponds to each pixel 110p of the display device 110 in the above embodiment.

In FIG. 8A, a horizontal axis represents the angle of the light-emitting area with respect to an optical axis, and a vertical axis represents the normalized luminous intensity obtained by dividing the luminous intensity at the angle by the luminous intensity on the optical axis. As illustrated in FIG. 8A, a display device according to the first example was set on the simulation software such that light emitted from each light-emitting area has a light distribution pattern in which the luminous intensity in a direction at an angle θ with respect to the optical axis is represented by cos θ times the luminous intensity on the optical axis. That is, in the first example, the light emitted from each light-emitting area has a strict Lambertian light distribution.

In the second to twelfth examples, the light emitted from each light-emitting area was set on the simulation software so as to have a light distribution pattern in which the luminous intensity in the direction at the angle θ with respect to the optical axis is represented by cosⁿθ times the luminous intensity on the optical axis. In the second example, n=2, and n was set so as to increase by 1 in the order from the second to twelfth examples.

When a light distribution pattern of light emitted from a pixel of the LCD in one plane was investigated, the light distribution pattern was found to be a light distribution pattern as indicated by a thin broken line in FIG. 8A. As described above, it was found that this light distribution pattern can be approximated to a light distribution pattern in which the luminous intensity in the direction at the angle θ with respect to the optical axis is represented by cos²⁰θ times the luminous intensity on the optical axis. Therefore, in the reference example, setting was performed on the simulation software such that a light distribution pattern is provided in which the luminous intensity of each light-emitting area in the direction at the angle θ with respect to the optical axis is represented by cos²⁰θ times the luminous intensity on the optical axis.

The imaging optical systems in the first to twelfth examples and the reference example were all set so as to have a telecentric property on the first image side.

Subsequently, for each of the first to twelfth examples and the reference example, the luminance distribution of the second image formed when the luminance of all the light-emitting areas was set uniform was simulated. At this time, the second image was a rectangle with a long side of 111.2 mm and a short side of 27.8 mm. At this time, the plane on which the second image is formed was divided into square areas each with a side of 1 mm, and the luminance value of each area was simulated.

In addition, the uniformity of luminance in the second image was evaluated. The “uniformity of luminance” refers to a value representing the proportion of the minimum value to the maximum value of luminance in the second image in percentage. The results are shown in FIG. 8B. In FIG. 8B, a horizontal axis represents each example and the reference example, and a vertical axis represents the uniformity of luminance.

As illustrated in FIG. 8B, it was found that as n increases, the uniformity of luminance decreases. This is because the luminance at a position away from the center in the second image decreases as n increases. In particular, in the eleventh example, that is, when n=11, the uniformity of luminance was found to be 30%. For a viewer to easily distinguish the second image from a region where the second image is not formed, it is conceivable that the uniformity of the luminance in the second image may be 30% or more.

Consequently, it was found that when the imaging optical system is configured so as to have a substantially telecentric property, light emitted from the display device preferably has a substantially Lambertian light distribution To suppress luminance unevenness in the first image and the second image. Specifically, it was found that in cosⁿθ being an approximate expression of the light distribution pattern, n is preferably 11 or less, more preferably 1. Although the uniformity of luminance in the second image IM2 decreases as n deviates from 1 as described above, a predetermined luminance distribution can be provided in advance in the display luminance of the display device 110 so that such unevenness of the luminance can be compensated for. For example, when the luminance of an outer edge portion of the second image IM2 is likely to be lower than the luminance of a central portion thereof due to passage of light emitted from each pixel 110p of the display device 110 through the imaging optical system 120, the display device 110 may be controlled such that the output of the LED elements 112 of the pixel 110p on the outer edge side of the display device 110 is higher than the output of the LED elements 112 of the pixel 110p on the central side.

### Second Embodiment

A second embodiment is described below.

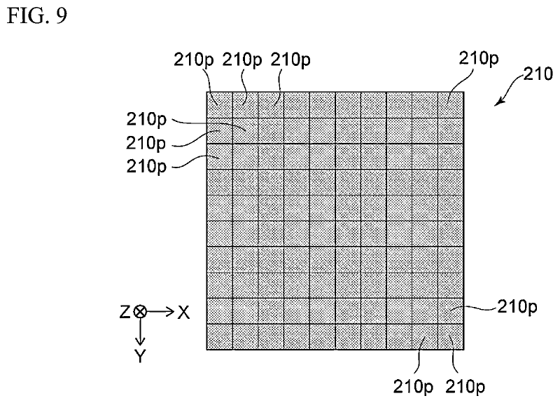

FIG. 9 is a plan view illustrating a display device in the present embodiment.

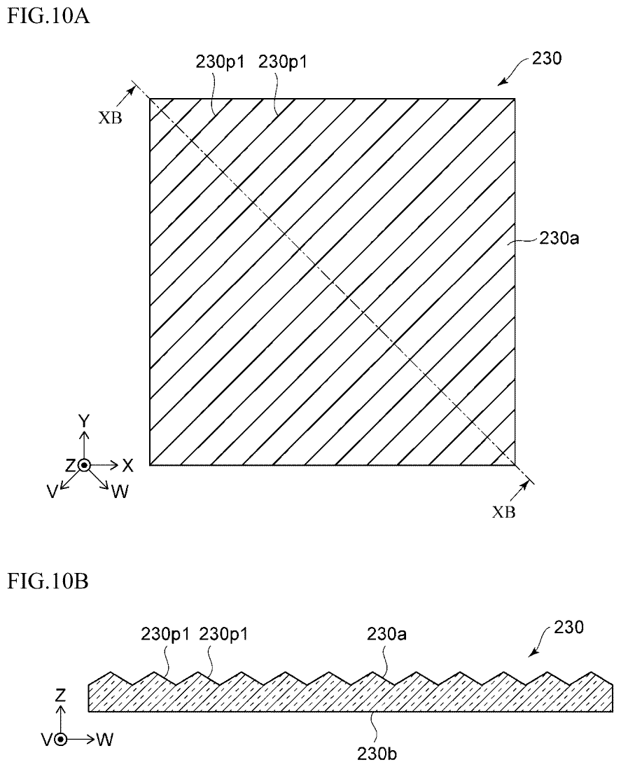

FIG. 10A is a plan view illustrating a prism sheet in the present embodiment.

FIG. 10B is an end view taken along line XB-XB illustrated in FIG. 10A.

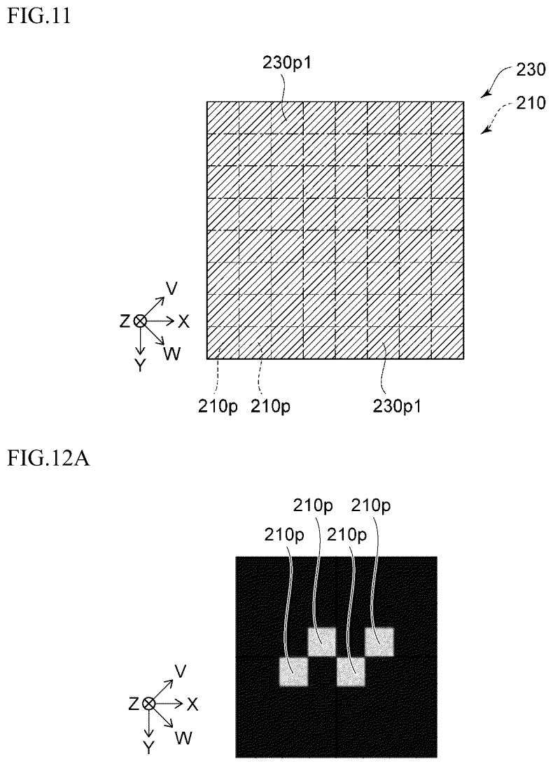

FIG. 11 is a plan view illustrating the display device and the prism sheet in the present embodiment.

As illustrated in FIG. 9, in a display device 210 of the present embodiment, pixels 210p are arranged in a matrix along the third direction (X direction) and the fourth direction (Y direction). That is, in the first embodiment, as illustrated in FIG. 2, one pixel 110p is disposed in every four unit regions 110u; however, in the present embodiment, the pixel 210p is disposed in each of all the unit regions.

As illustrated in FIGS. 10A and 10B, a first prism sheet 230 of the present embodiment has a first surface 230a on which light emitted from the display device 210 is incident, and a second surface 230b from which light is emitted toward the input element 121. On the first surface 230a, stripe-shaped first prisms 230p1 extending in a first direction are formed. No prism is formed on the second surface 230b, and the second surface 230b is flat. The first direction is a direction inclined with respect to the third direction by 45°. The arrangement direction of the first prisms 230p1 is defined as a second direction. The second direction is a direction inclined with respect to the fourth direction by 45°.

As illustrated in FIGS. 10A, 10B, and 11, in the present embodiment, the third direction in which the pixels 210p of the display device 210 are arranged is the X direction, and the fourth direction in which the pixels 210p are arranged is the Y direction. The first direction in which the first prisms 230p1 of the first prism sheet 230 extend is referred to as a V direction, and the second direction in which the plurality of first prisms 230p1 are arranged is referred to as a W direction. An angle between the V direction and the W direction is 90°, and the V direction and the W direction are orthogonal to the Z direction. Therefore, the X direction (third direction), the Y direction (fourth direction), the U direction (first direction), and the V direction (second direction) are parallel to the second surface 230b of the first prism sheet 230. As illustrated in FIG. 11, the arrangement cycle of the first prisms 230p1 is shorter than the arrangement cycle of the pixels 210p.

An operation of the present embodiment is described below.

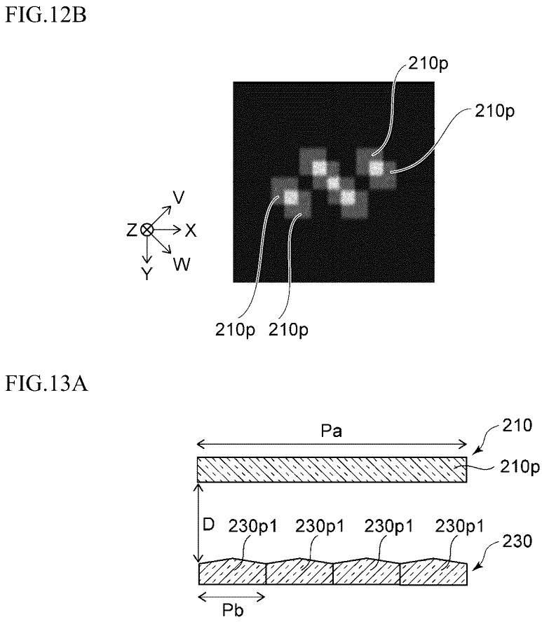

FIG. 12A is a view illustrating a state in which some pixels 210p are lit in the display device 210.

FIG. 12B is a view illustrating a pixel enlarged by the first prism 230p1.

As illustrated in FIG. 12A, the pixel 210p is selectively lit in the display device 210. In the example illustrated in FIG. 12A, four pixels 210p are lit, and the other pixels 210p are not lit.

As illustrated in FIG. 12B, when light emitted from each pixel 210p is incident on the first prism 230p1 of the first prism sheet 230, the light is separated along the W direction. Thus, when viewed from the viewer 14 side, each pixel 210p appears to be separated into two in the W direction. However, in the present embodiment, the two separated pixels 210p are not spaced apart from each other but partially overlap each other. A region where the two pixels 210p overlap is relatively bright. Around this bright region, a relatively dark region where only one pixel 210p is disposed is present. Thus, the light emitted from each pixel 210p is diffused so as to have one peak along the W direction. As a result, a picture displayed by the display device 210 becomes smooth.

The relationship between the sizes of the components of the light source unit 11 is described below.

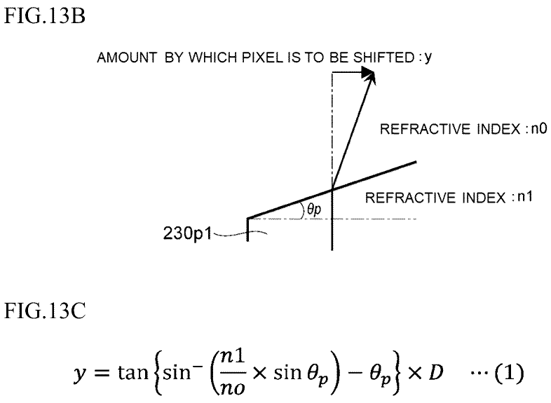

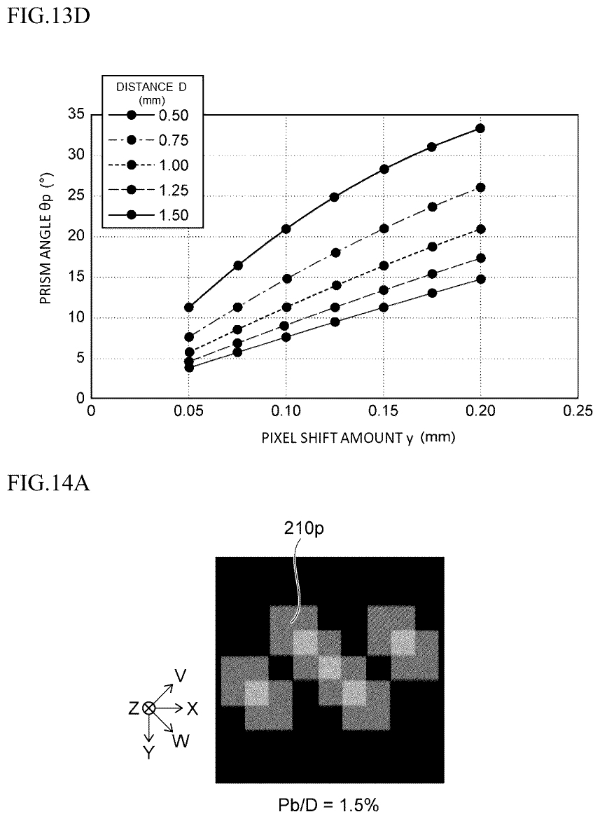

FIG. 13A is an end view illustrating the display device 210 and the first prism sheet 230 of the present embodiment.

FIG. 13B is an optical diagram illustrating the first prism 230p1 of the present embodiment.

FIG. 13C is an equation representing the relationship among a distance D, a prism angle θp, refractive indices n0 and n1, and a pixel shift amount y.

FIG. 13D is a graph showing the relationship between the distance D and the prism angle θp required to obtain a desired pixel shift amount y, where a horizontal axis represents the pixel shift amount y and a vertical axis represents the prism angle θp.

As illustrated in FIG. 13A, a distance between the display device 210 and the first prism sheet 230 is denoted by D. The arrangement cycle (pixel pitch) of the pixels 210p in the display device 210 is denoted by Pa. The arrangement cycle (prism pitch) of the first prisms 230p1 in the first prism sheet 230 is denoted by P2.

As illustrated in FIG. 13B, an angle between the surface of the first prism 230p1 and the second surface 230b is denoted by the prism angle θp. An apex angle of the first prism 230p1 is (180−2θp)°. The prism angle θp is greater than 0° and equal to or less than 45°, and is preferably in a range from 1° to 40°. Consequently, the apex angle of the first prism 230p1 is 90° or more and less than 180°, and is preferably in a range from 100° to 178°. The refractive index of the first prism sheet 230 is denoted by n1, the refractive index of an environment in which the first prism sheet 230 is placed, for example, the air, is denoted by n0, and the amount by which the pixel 210p is to be shifted (pixel shift amount) is denoted by y.

To reduce the size of the light source unit 11, the distance D is preferably short. However, when the distance D is too short, because the proportion of light that is totally reflected by the surfaces of the first prisms 230p1 increases, the light use efficiency decreases. To suppress the total reflection, the prism angle θp may be reduced; however, when the prism angle θp is reduced, the pixel shift amount y is difficult to obtain. In other words, the shortening of the distance D and the reduction of the prism angle θp are in a trade-off relationship with respect to the desired pixel shift amount y.

The pixel shift amount y can be expressed as a function of the distance D, the prism angle θp, and the refractive indices n0 and n1 as in Equation (1) shown in FIG. 13C. When several distances D and refractive indexes n0 and n1 in Equation (1) are graphed, the graph of FIG. 13D is obtained.

As shown in FIG. 13D, to increase the pixel shift amount y, the distance D needs to be increased or the prism angle θp needs to be increased. For example, in a case in which the pixel pitch Pa is 0.1 mm, when a region irradiated with light is to be shifted by half the pixel pitch Pa, the pixel shift amount y is 0.05 mm. In this case, when the distance D is 1.50 mm, the prism angle θp is about 4°, and when the distance D is 0.50 mm, the prism angle θp is about 11°.

The ratio of the prism pitch Pb to the distance D is preferably 10% or less, more preferably 7.5% or less, even more preferably 5% or less, even more preferably 2.5% or less.

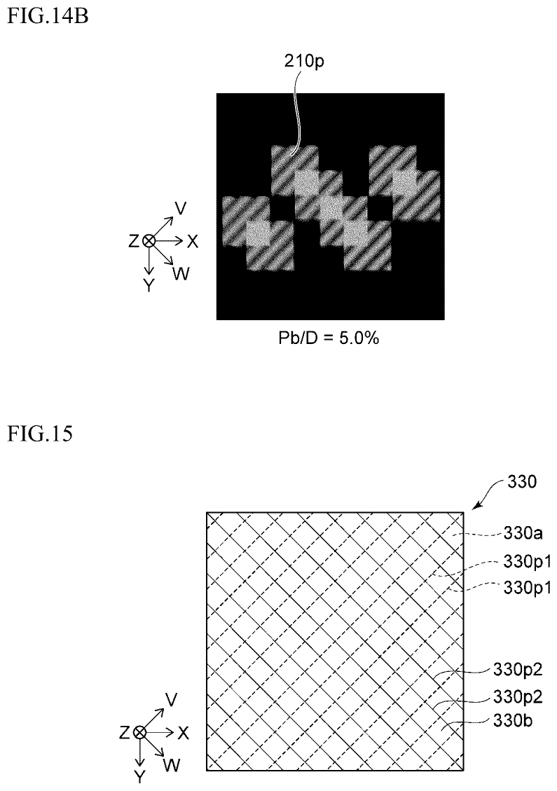

FIGS. 14A and 14B are views illustrating the distribution of light transmitted through the first prism sheet 230, where FIG. 14A illustrates a case in which the ratio of the prism pitch Pb to the distance D (Pb/D) is 1.5% and FIG. 14B illustrates a case in which the ratio (Pb/D) is 5.0%.

As illustrated in FIG. 14A, when the ratio (Pb/D) is 1.5%, the prism pitch Pb is hardly reflected in the distribution of the light transmitted through the first prism sheet 230, but as illustrated in FIG. 14B, when the ratio (Pb/D) is 5.0%, the prism pitch Pb is clearly reflected in the distribution of the light transmitted through the first prism sheet 230. Therefore, the smaller the ratio (Pb/D) is, the better the quality of a picture transmitted through the first prism sheet 230 is.

Subsequently, an effect of the present embodiment is described. According to the present embodiment, light emitted from each pixel 210p of the display device 210 is separated into two pixels partially overlapping each other by the first prism 230p1, so that a picture can be smoothed. The configuration, operation, and effects of the present embodiment other than those described above are the same as those of the first embodiment.

### Third Embodiment

A third embodiment is described below.

FIG. 15 is a plan view illustrating a first prism sheet 330 of the present embodiment.

As illustrated in FIG. 15, in the present embodiment, the first prism sheet 330 is provided instead of the first prism sheet 230 in the second embodiment.

The first prism sheet 330 has a first surface 330a on which light emitted from the display device 210 is incident and a second surface 330b from which light is emitted toward the input element 121. On the first surface 330a, stripe-shaped first prisms 330p1 extending in the first direction (V direction) are formed. On the second surface 330b, stripe-shaped second prisms 330p2 extending in the second direction (W direction) are formed. The first direction (V direction) is inclined with respect to the third direction (X direction) by 45°, and the second direction (W direction) is inclined with respect to the fourth direction (Y direction) by 45°. Therefore, the second direction (W direction) is orthogonal to the first direction (V direction).

An operation of the present embodiment is described below.

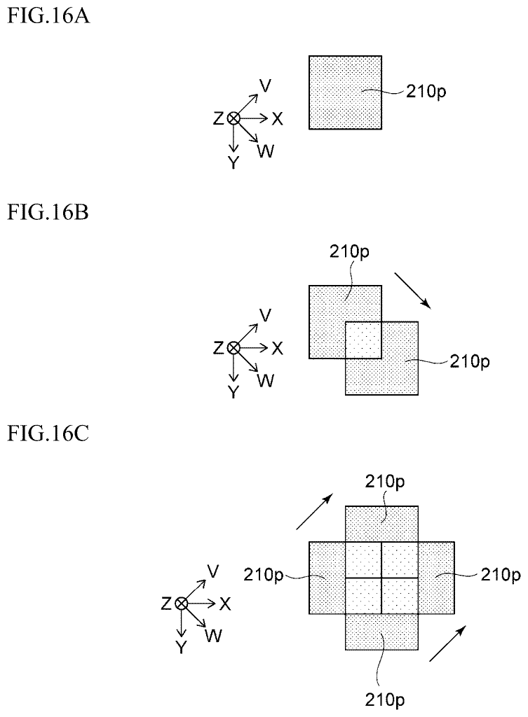

FIG. 16A is a view illustrating one pixel 210p in the present embodiment.

FIG. 16B is a view illustrating a pixel enlarged by the first prism 330p1.

FIG. 16C is a view illustrating a pixel further enlarged by the second prism 330p2.

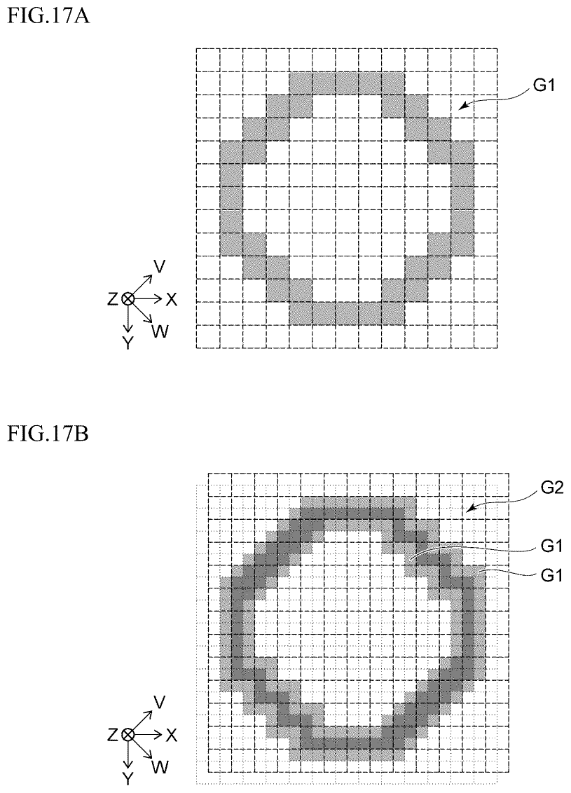

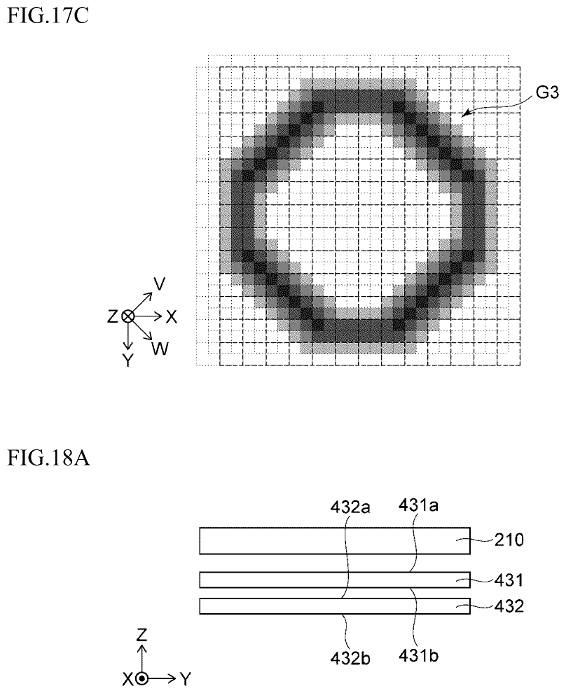

FIG. 17A is a view illustrating a picture displayed by the display device 210 in the present embodiment.

FIG. 17B is a view illustrating a picture enlarged by the first prism 330p1.

FIG. 17C is a view illustrating a picture further enlarged by the second prism 330p2.

First, one pixel is described.

As illustrated in FIG. 16A, one pixel 210p of the display device 210 is assumed to be lit.

As illustrated in FIG. 16B, when light emitted from the pixel 210p is incident on the first prism 330p1, the light is separated into two pixels 210p along the W direction. At this time, the two pixels 210p are separated so as to partially overlap each other. For example, the two pixels 210p are shifted by 0.5 pixels.

The two pixels 210p separated by the first prism 330p1 are each further separated into two pixels 210p along the V direction by the second prism 330p2 as illustrated in FIG. 16C. The pixel shift amount at this time is also an amount by which the two pixels 210p partially overlap each other, for example, corresponds to 0.5 pixels. Thus, light emitted from one pixel 210p is enlarged to a region where four pixels 210p overlap one another.

The entire picture is described below.

As illustrated in FIG. 17A, the display device 210 is assumed to display a certain picture G1.

As illustrated in FIG. 17B, light emitted from a plurality of pixels 210p constituting the picture G1 is separated by the first prism 330p1 along the W direction by, for example, 0.5 pixels. Thus, a picture G2 in which two pictures G1 of the same shape overlap each other with a shift of 0.5 pixels is synthesized.

As illustrated in FIG. 17C, the light separated by the first prism 330p1 is separated by the second prism 330p2 along the V direction by, for example, 0.5 pixels. Thus, a picture G3 in which two pictures G2 of the same shape overlap each other with a shift of 0.5 pixels is formed. The picture G3 is a picture in which four pictures G1 overlap one another. As a result, the picture G1 displayed by the display device 210 is smoothed by passage through the first prism sheet 330.

Subsequently, an effect of the present embodiment is described.

In the present embodiment, because the first prisms 330p1 are provided on the first surface 330a of the first prism sheet 330 and the second prisms 330p2 are provided on the second surface thereof, a picture is separated along the two directions of the W direction and the V direction. Thus, the picture becomes smoother than in the second embodiment. The configuration, operation, and effects of the present embodiment other than those described above are the same as those of the second embodiment.

### Fourth Embodiment

A fourth embodiment is described below.

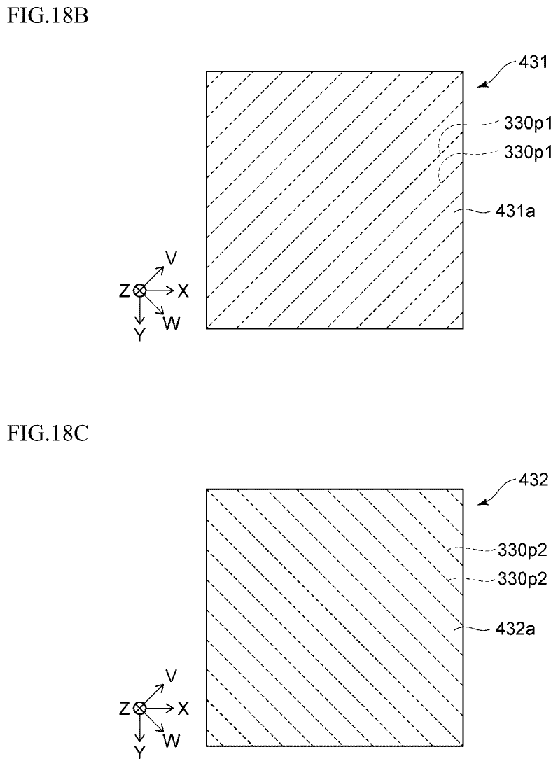

FIG. 18A is a side view illustrating the display device 210, a first prism sheet 431, and a second prism sheet 432 of a light source unit according to the present embodiment.

FIG. 18B is a plan view illustrating the first prism sheet 431 of the present embodiment.

FIG. 18C is a plan view illustrating the second prism sheet 432 of the present embodiment.

As illustrated in FIGS. 18A to 18C, the present embodiment is different from the third embodiment in that the first prisms 330p1 and the second prisms 330p2 are separately disposed on two prism sheets. The light source unit according to the present embodiment is provided with the first prism sheet 431 and the second prism sheet 432, and the second prism sheet 432 is disposed between the first prism sheet 431 and the input element 121.

The first prisms 330p1 are disposed on a first surface 431a of the first prism sheet 431, and the second prisms 330p2 are disposed on a first surface 432a of the second prism sheet 432. The first prisms 330p1 extend in a stripe shape in the first direction (V direction), and the second prisms 330p2 extend in a stripe shape in the second direction (W direction). The first surface 431a of the first prism sheet 431 and the first surface 432a of the second prism sheet 432 are surfaces facing the display device 210.

The first prisms 330p1 may be disposed on a second surface 431b of the first prism sheet 431, and the second prisms 330c2 may be disposed on a second surface 432b of the second prism sheet 432. The second surface 431b of the first prism sheet 431 and the second surface 432b of the second prism sheet 432 are surfaces facing the input element 121.

Also in the present embodiment, like the third embodiment, a picture displayed by the display device 210 can be smoothed. The configuration, operation, and effects of the present embodiment other than those described above are the same as those of the third embodiment.

### Fifth Embodiment

A fifth embodiment is described below.

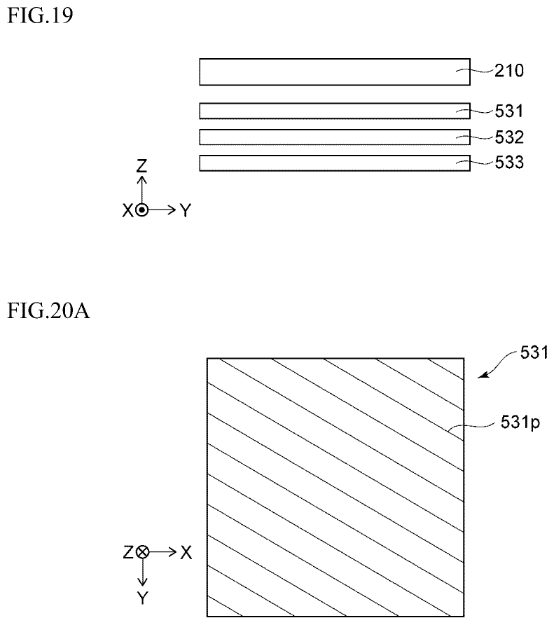

FIG. 19 is a side view illustrating the display device 210, a first prism sheet 531, a second prism sheet 532, and a third prism sheet 533 of a light source unit according to the present embodiment.

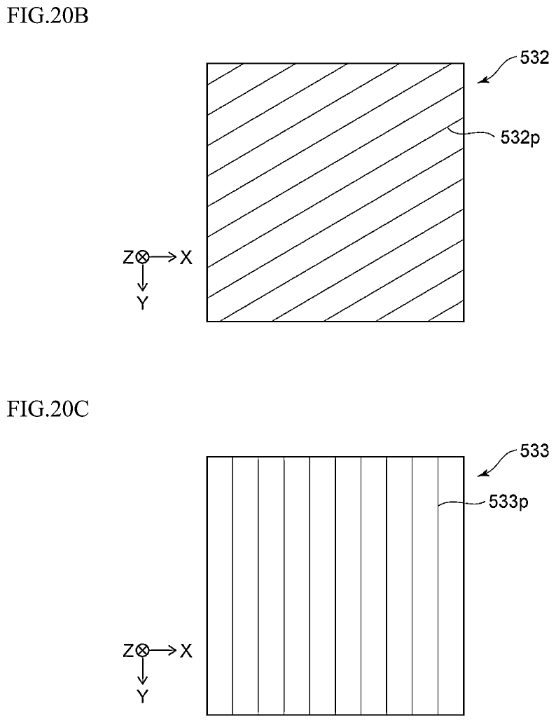

FIG. 20A is a plan view illustrating the first prism sheet 531 of the present embodiment.

FIG. 20B is a plan view illustrating the second prism sheet 532 of the present embodiment.

FIG. 20C is a plan view illustrating the third prism sheet 533 of the present embodiment.

As illustrated in FIG. 19, in the present embodiment, three prism sheets are provided between the display device 210 and the input element 121. That is, the first prism sheet 531, the second prism sheet 532, and the third prism sheet 533 are arranged in this order along a direction from the display device 210 to the input element 121.

First prisms 531p are formed on the first prism sheet 531, second prisms 532p are formed on the second prism sheet 532, and third prisms 533p are formed on the third prism sheet 533. The first prism 531p, the second prism 532p, and the third prism 533p are all stripe-shaped and form an angle of 120° with one another. Each prism may be formed on either surface of a corresponding one of the prism sheets. Two prisms may be formed on both surfaces of one prism sheet.

An operation of the present embodiment is described below.

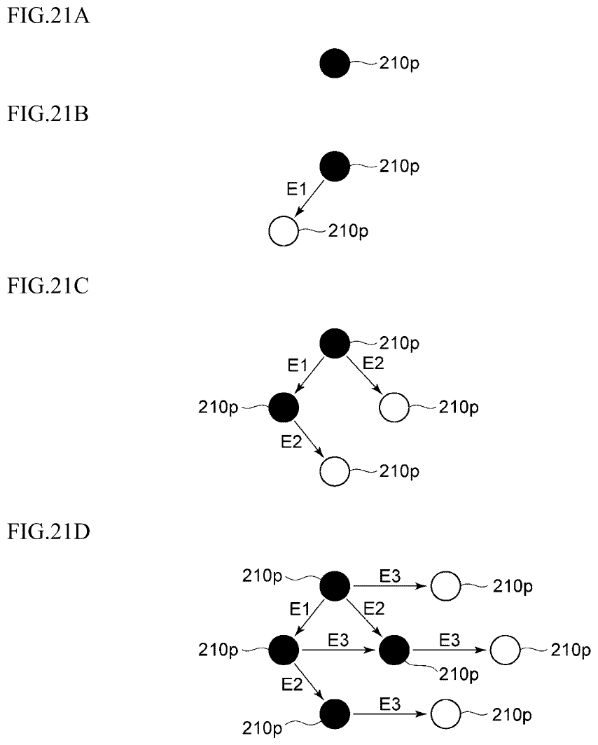

FIGS. 21A to 21D are schematic views illustrating the operation of the present embodiment.

As illustrated in FIG. 21A, one pixel 210p is assumed to be lit.

As indicated by an arrow E1 in FIG. 21B, light emitted from the pixel 210p is separated by the first prism 531p, and thus separation into two pixels 210p is performed.

As indicated by an arrow E2 in FIG. 21C, the two pixels 210p are each separated into two by the second prism 532p, and thus separation into four pixels 210p is performed.

As indicated by an arrow E3 in FIG. 21D, the four pixels 210p are each further separated into two by the third prism 533p. However, at this time, because two pixels 210p overlap each other at one position, seven pixels 210p are finally formed. In this way, light emitted from one pixel 210p is separated into the seven pixels 210p.

In this way, according to the present embodiment, light emitted from the pixel can be expanded in three directions forming an angle of 120° with each other, and a picture can be made smoother. The configuration, operation, and effects of the present embodiment other than those described above are the same as those of the fourth embodiment.

### Sixth Embodiment

A sixth embodiment is described below.

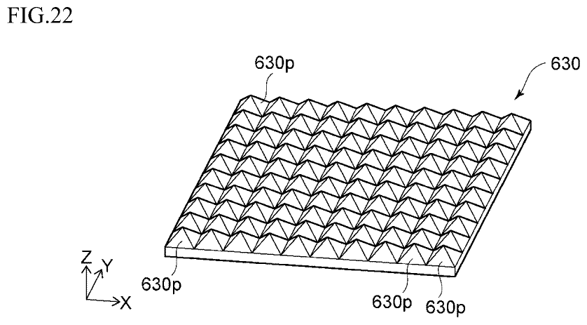

FIG. 22 is a perspective view illustrating a first prism sheet of the present embodiment.

As illustrated in FIG. 22, a first prism sheet 630 is provided in the present embodiment. First prisms 630p are formed on the first prism sheet 630. The first prism 630p does not have a stripe shape but is, for example, a protruding portion. A plurality of the first prisms 630p are arranged in a matrix along the first direction (V direction) and the second direction (W direction). In the example illustrated in FIG. 22, the shape of the first prism 630p is a pyramid shape (quadrangular pyramid shape). However, the shape of the first prism 630p is not limited thereto, and may be, for example, a circular cone shape or a hexagonal cone shape. The first prism 630p may be a recessed portion.

The arrangement directions of the first prisms 630p are also not limited to the V direction and the W direction, and may be the X direction and the Y direction, that is, the same as the arrangement directions of the pixels of the display device. The configuration, operation, and effects of the present embodiment other than those described above are the same as those of the third embodiment.

### Seventh Embodiment

A seventh embodiment is described below.

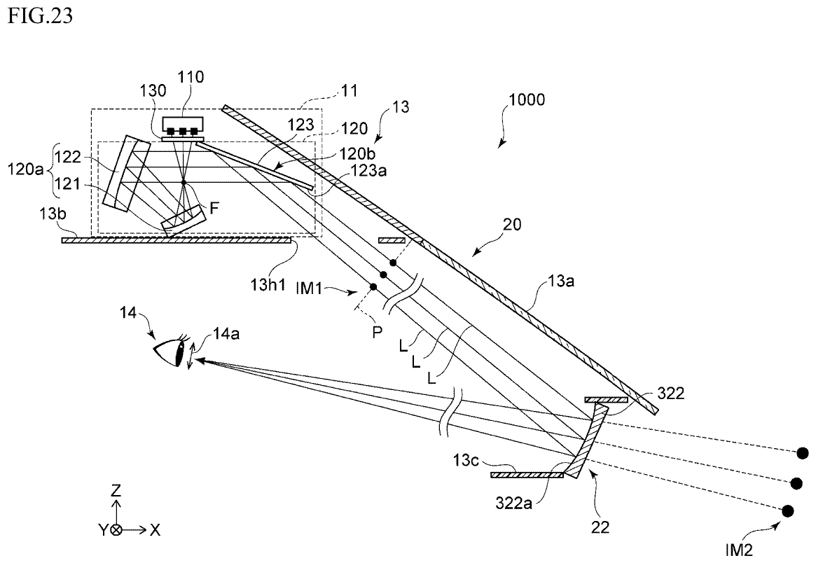

FIG. 23 is an end view illustrating a video display apparatus according to the present embodiment.

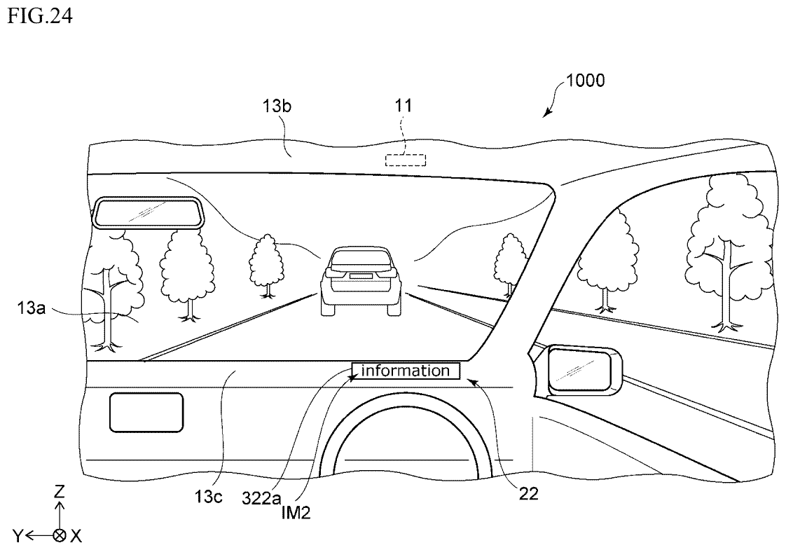

FIG. 24 is a schematic view illustrating scenery viewed from a viewer in a driver's seat in the present embodiment.

As illustrated in FIG. 23, an automobile 1000 according to the present embodiment includes the vehicle 13 and a video display apparatus 20 fixed to the vehicle 13. The video display apparatus 20 includes the light source unit 11 and a reflection unit 22. The video display apparatus 20 according to the present embodiment is different from the video display apparatus 10 according to the first embodiment in that a mirror surface 322a of a mirror 322 of the reflection unit 22 also serves as a reflecting surface that allows the viewer 14 to visually recognize the second image IM2.

The configuration of the light source unit 11 in the video display apparatus 20 is the same as that in the first embodiment. The light source unit 11 is disposed on the ceiling portion 13b of the vehicle 13. The reflection unit 22 is disposed on the dashboard portion 13c of the vehicle 13. The reflection unit 22 includes the mirror 322. The mirror surface 322a of the mirror 322 is, for example, a concave surface. The mirror surface 322a is disposed at a position and at an angle so as to face the eye box 14a of the viewer 14 when the viewer 14 is in the driver's seat of the vehicle 13. For example, the mirror surface 322a is directed to a direction between the −X direction (backward) and the +Z direction (upward). The angle of the mirror surface 322a can be finely adjusted in accordance with the position of the eye box 14a of the viewer 14.

An operation of the present embodiment is described below.

The principal ray L emitted from the light source unit 11 travels in a direction between the +X direction (forward) and the −Z direction (downward), is reflected by the mirror surface 322a of the mirror 322 of the reflection unit 22, travels in the direction between the −X direction (backward) and the +Z direction (upward), and is incident on the eye box 14a of the viewer 14. The path of the principal ray L from the light source unit 11 toward the reflection unit 12 is located on an inner side of the front windshield 13a of the vehicle 13 and substantially along the front windshield 13a. The principal ray L forms the first image IM1 at the position P between the light source unit 11 and the reflection unit 22. At this time, the first image IM1 is smoothed by the action of the first prism sheet 130.

Thus, as illustrated in FIGS. 23 and 24, the viewer 14 can visually recognize the second image IM2 being a virtual image behind the mirror surface 322a of the dashboard portion 13c. The second image IM2 is formed at a distance of, for example, 3 m from the mirror surface 322a. Therefore, the viewer 14 can view the second image IM2 without largely moving the focal distance of the eye from a state in which the viewer 14 is viewing distant scenery through the front windshield 13a.

Subsequently, an effect of the present embodiment is described.

As in the first embodiment, the video display apparatus 20 according to the present embodiment is divided into the light source unit 11 and the reflection unit 22, and fixed to different positions in the vehicle 13. The video display apparatus 20 requires a long optical path length to form the second image IM2 at a position several meters ahead; however, by disposing the light source unit 11 and the reflection unit 22 separately from each other, a part of the optical path length can be formed by using the internal space of the vehicle 13. Thus, an entire necessary optical path length need not be formed inside the video display apparatus 20, so that the video display apparatus 20 can be reduced in size.

In the video display apparatus 20, only the mirror 322 is provided in the reflection unit 22. Thus, the configuration of the reflection unit 22 can be simplified, and the reflection unit 22 can be reduced in size.

Moreover, by using, as a reflecting surface, the mirror surface 322a disposed on the dashboard portion 13c, the viewer 14 can reliably view the second image IM2 without being affected by the background of the reflecting surface. The configuration, operation, and effects of the present embodiment other than those described above are the same as those of the first embodiment.

The mirror 322 of the reflection unit 22 may be formed of a half mirror or a transparent plate. Even in this case, when the interior of the dashboard portion 13c is darkened, the interior of the dashboard portion 13c can be inhibited from being viewed by the viewer 14. Alternatively, the mirror surface 322a of the mirror 322 may be black enough to sufficiently reflect the principal ray L emitted from the light source unit 11. This can suppress a decrease in visibility due to reflection of external light or the like by the mirror surface 322a of the mirror 322. The mirror 322 may be disposed so as to be continuous with the surface of the dashboard portion 13c. Thus, no hole needs to be formed in the dashboard portion 13c, and the designability of the interior of the automobile 1000 is improved.

### Eighth Embodiment

An eighth embodiment is described below.

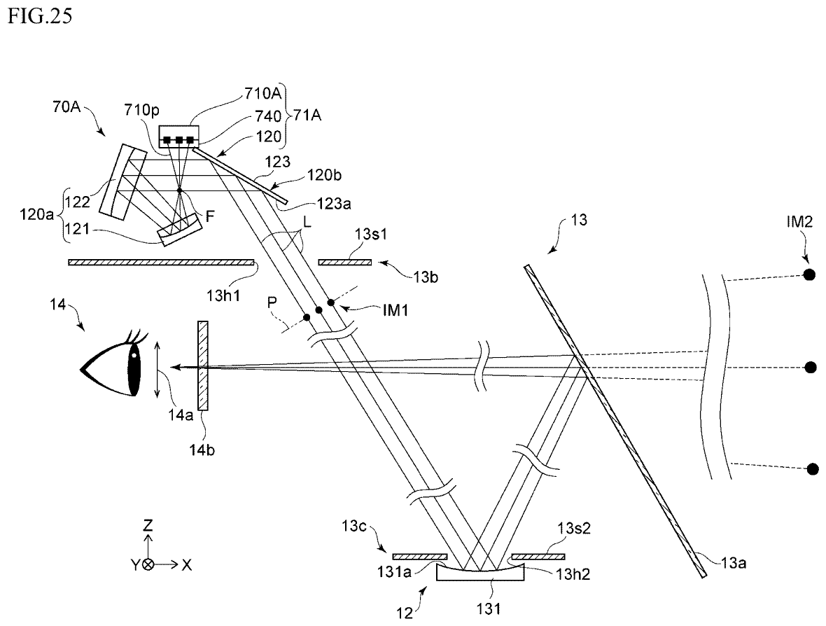

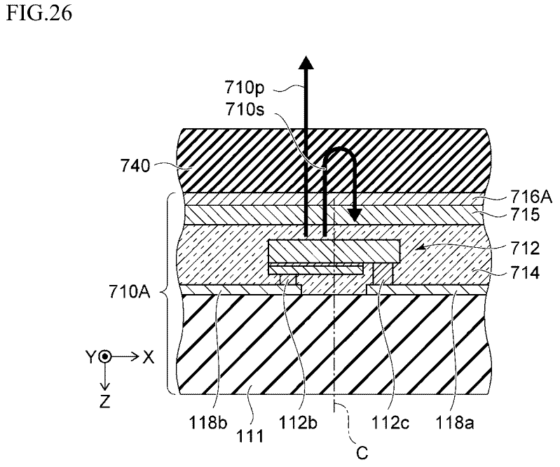

FIG. 25 is an end view illustrating a video display apparatus according to the present embodiment.

FIG. 26 is an enlarged cross-sectional view illustrating a part of a display device and a reflective polarizing element illustrated in FIG. 25.

As illustrated in FIGS. 25 and 26, a video display apparatus 70A according to the present embodiment is different from the video display apparatus 10 according to the first embodiment in that a display device 710A is provided instead of the display device 110 and a reflective polarizing element 740 is further provided. The display device 710A in the present embodiment is different from the display device 110 in the first embodiment in that light exit surfaces of LED elements 712 are substantially flat and a protective layer 714, a wavelength conversion member 715, and a light scattering member 716A are further provided. The other configurations of the display device 710A are the same as those of the display device 110 in the first embodiment. Like the light source unit 11 according to the first embodiment, a light source unit 71A according to the present embodiment includes the first prism sheet 130. However, FIG. 25 does not illustrate the first prism sheet 130.

The protective layer 714 covers a plurality of the LED elements 712 arranged in a matrix. For the protective layer 714, for example, a light-transmitting material such as a polymer material having a sulfur (S)-containing substituent or a phosphorus (P) atom-containing group, or a high refractive index nanocomposite material obtained by introducing inorganic nanoparticles with a high refractive index into a polymer matrix such as polyimide can be used.

The wavelength conversion member 715 is disposed on the protective layer 714. The wavelength conversion member 715 includes one or more kinds of wavelength conversion materials such as a general phosphor material, a perovskite phosphor material, or a quantum dot (QD). Light emitted from each LED element 712 is incident on the wavelength conversion member 715. In response to entry of the light emitted from each LED element 712, the wavelength conversion material included in the wavelength conversion member 715 emits light with a light emission peak wavelength different from the light emission peak wavelength of each LED element 712. The light emitted by the wavelength conversion member 715 has a substantially Lambertian light distribution.

The light scattering member 716A includes, for example, a resin member having a light-transmitting property and light scattering particles or holes disposed in the resin member. Examples of the resin member include polycarbonate. Examples of the light scattering particles include a material having a refractive index different from that of the resin member, such as titanium oxide. The light scattering effect may be obtained by roughening the surface of the light scattering member 716A to provide irregularities.

Examples of the reflective polarizing element 740 that can be used include a multilayer thin film layered polarizing plate in which thin film layers with different polarization characteristics are layered. The reflective polarizing element 740 is disposed on the display device 710A. In the present embodiment, the reflective polarizing element 740 is disposed on the light scattering member 716A. Therefore, light emitted from the LED element 712 and the wavelength conversion member 715 is incident on the reflective polarizing element 740. The reflective polarizing element 740 transmits first polarized light 710p of the light emitted from the display device 710A, and reflects second polarized light 710s toward the display device 710A. The vibration direction of an electric field of the second polarized light 710s is substantially orthogonal to the vibration direction of an electric field of the first polarized light 710p.

In the present embodiment, the first polarized light 710p is P-polarized light, and the second polarized light 710s is S-polarized light. The “P polarized light” means light in which the vibration direction of an electric field is substantially parallel to the XY plane. The “S polarized light” means light in which the vibration direction of the electric field is substantially perpendicular to the XY plane including incident light and reflected light.

The viewer 14 who drives the vehicle 13 may wear polarized sunglasses 14b to reduce the glare of sunlight or the like reflected by a puddle or the like in front of the vehicle 13 and transmitted through the front windshield 13a. In this case, because the sunlight or the like reflected by the puddle or the like is particularly reduced in components corresponding to P-polarized light when viewed from the front windshield 13a at the time of reflection, the polarized sunglasses 14b are designed so as to block most of S-polarized light. Consequently, when the viewer 14 wears the polarized sunglasses 14b, most of the S-polarized light included in the light emitted by the display device 710A is also blocked by the polarized sunglasses 14b, which may make it difficult for the viewer 14 to visually recognize the second image IM2. The P-polarized light and the S-polarized light in the present specification are physically defined by the presence of a reflective object such as the puddle described above.

In the present embodiment, the reflective polarizing element 740 transmits the first polarized light 710p of the light emitted from the display device 710A, and reflects second polarized light 710s. Most of the first polarized light 710p transmitted through the reflective polarizing element 740 is incident on the eye box 14a without being blocked by the polarized sunglasses 14b after passing through the inner surfaces of the imaging optical system 120, the reflection unit 12, and the front windshield 13a. An incident angle of the first polarized light 710p on the inner surface of the front windshield 13a is set different from the Brewster's angle.

Specifically, as illustrated in FIG. 26, the wavelength conversion member 715 is irradiated with the light emitted from the LED element 712. Thus, the wavelength conversion member 715 is excited to emit light with a light emission peak wavelength longer than the light emission peak wavelength of the light emitted from the LED element 712. In the present embodiment, the light emitted from the display device 710A includes light emitted from the LED elements 712 and light emitted from the wavelength conversion member 715. Hereinafter, of the light emitted from the display device 710A, the light emitted from the LED element 712 is also referred to as “short-wavelength light,” and the light emitted from the wavelength conversion member 715 is also referred to as “long-wavelength light.” However, most of the light emitted from the LED element 712 may be absorbed by the wavelength conversion member 715.

Most of the first polarized light 710p included in the short-wavelength light and the long-wavelength light passes through the reflective polarizing element 740 and is emitted from the imaging optical system 120. Most of the second polarized light 710s included in the short-wavelength light and the long-wavelength light is reflected by the reflective polarizing element 740. Apart of the second polarized light 710s reflected by the reflective polarizing element 740 is scattered and reflected by the components of the display device 710A such as the light scattering member 716A and the wavelength conversion member 715. Due to the scattering reflection, a part of the second polarized light 710s is converted into the first polarized light 710p. A part of the first polarized light 710p converted from the second polarized light 710s passes through the reflective polarizing element 740 and is emitted from the light source unit 71A. Therefore, the luminance of the first image IM1 can be improved while increasing the proportion of the first polarized light 710p included in the light emitted from the light source unit 71A. Because the luminance of the first image IM1 is improved, the luminance of the second image IM2 is also improved. Thus, the viewer 14 can easily view the second image IM2.

In addition, a part of the short-wavelength light included in the second polarized light 710s may be incident on the wavelength conversion member 715 after being reflected by the reflective polarizing element 740. In this case, the wavelength conversion member 715 can be expected to absorb the short-wavelength light of the second polarized light 710s and newly emit long-wavelength light. Each of the scattered reflected light and the emitted light has a substantially Lambertian light distribution. In addition, the reflective polarizing element 740 itself may scatter and reflect the second polarized light 710s. Also in such a case, a part of the second polarized light 710s is converted into the first polarized light 710p by scattering reflection.

In the present embodiment, one reflective polarizing element 740 covers all pixels of the display device 710A. However, the light source unit may include a plurality of reflective polarizing elements, and each reflective polarizing element may be disposed on a corresponding pixel. The configuration of the display device used in combination with the reflective polarizing element is not limited to that described above. For example, the display device may be configured with no light scattering member by using the light scattering reflection effect of the wavelength conversion member. In addition, the display device may be configured with no wavelength conversion member by using the scattering reflection effect of the light scattering member. In addition, as in the first embodiment, the display device may be configured with neither the wavelength conversion member nor the light scattering member by using the light scattering reflection effect of a plurality of recessed portions or a plurality of protruding portions provided on the light exit surface of the LED element.

An effect of the present embodiment is described below.

The light source unit 71A according to the present embodiment further includes the reflective polarizing element 740 that is disposed on the display device 710A and transmits the first polarized light 710p of light emitted from the display device 710A and reflects the second polarized light 710s of the light emitted from the display device 710A. Therefore, the luminance of the first image IM1 can be improved while increasing the proportion of the first polarized light 710p included in the light emitted from the light source unit 71A.

Light emitted from the reflective polarizing element 740 also has a substantially Lambertian light distribution. Therefore, the present embodiment can also provide the light source unit 71A that is small and can form the first image IM1 with high quality. Because the plurality of LED elements 712 are discretely mounted on the substrate 111, a granular feeling may occur in the first image IM1. The wavelength conversion member 715 has an effect of reducing the granular feeling. The light scattering member 716A can further reinforce the effect of reducing the granular feeling. The configuration, operation, and effects of the present embodiment other than those described above are the same as those of the first embodiment.

### Ninth Embodiment

A ninth embodiment is described below.

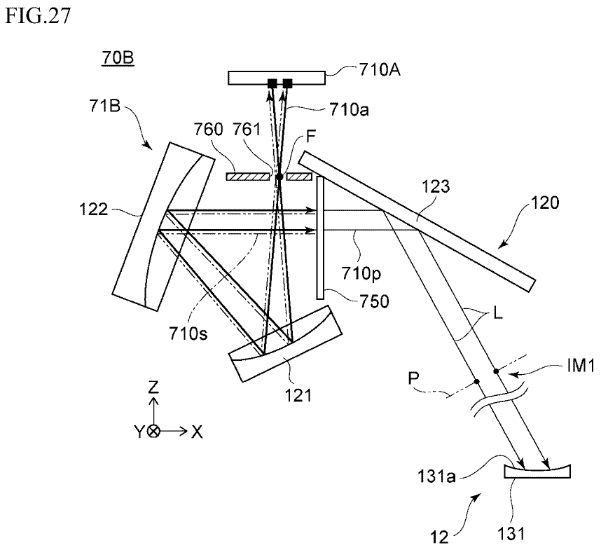

FIG. 27 is a side view illustrating a light source unit according to the present embodiment.

As illustrated in FIG. 27, a video display apparatus 70B according to the present embodiment is different from the video display apparatus 10 according to the first embodiment in that a light source unit 71B includes the display device 710A having the same configuration as that of the eighth embodiment instead of the display device 110 and further includes a reflective polarizing element 750 and a light-shielding member 760. In FIG. 27, only the light-shielding member 760 is illustrated in cross-section.

As the reflective polarizing element 750, for example, a wire grid type reflective polarizing element using a plurality of metal nanowires can be used. The reflective polarizing element 750 is disposed in a portion, where a plurality of principal rays L are substantially parallel to each other, in an optical path from the display device 710A to the reflection unit 12. In the present embodiment, the plurality of principal rays L are substantially parallel to each other on the optical path from the intermediate element 122 to the reflection unit 12, and the reflective polarizing element 750 is disposed between the intermediate element 122 and the output element 123.

The reflective polarizing element 750 transmits the first polarized light 710p being P-polarized light, and reflects the second polarized light 710s being S-polarized light back to the display device 710A. Specifically, light 710a including the first polarized light 710p and the second polarized light 710s is emitted from the display device 710A. The light 710a is incident on the reflective polarizing element 750 after passing through the input element 121 and the intermediate element 122.

The reflective polarizing element 750 transmits most of the first polarized light 710p included in the light 710a. Most of the first polarized light 710p transmitted through the reflective polarizing element 750 is emitted from the reflection unit 12 after passing through the output element 123.

The reflective polarizing element 750 reflects most of the second polarized light 710s included in the light 710a back along the optical path from the display device 710A to the reflective polarizing element 750. Specifically, the reflective polarizing element 750 has a flat plate shape. The reflective polarizing element 750 is substantially orthogonal to the principal ray L. The reflective polarizing element 750 specularly reflects most of the second polarized light 710s. Therefore, most of the second polarized light 710s reflected by the reflective polarizing element 750 returns to the display device 710A after passing through the intermediate element 122 and the input element 121 in this order.

A part of the second polarized light 710s having returned to the display device 710A is scattered and reflected by the components of the display device 710A such as the light scattering member 716A and the wavelength conversion member 715. Due to the scattering reflection, a part of the second polarized light 710s is converted into the first polarized light 710p. A part of the first polarized light 710p converted from the second polarized light 710s is transmitted through the reflective polarizing element 750 after passing through the input element 121 and the intermediate element 122. Most of the first polarized light 710p transmitted through the reflective polarizing element 750 is emitted from the reflection unit 12 after passing through the output element 123. Therefore, the luminance of the second image IM2 can be improved while increasing the proportion of the first polarized light 710p included in the light emitted from the video display apparatus 70B. Thus, the viewer 14 can easily view the second image IM2.

In addition, a part of the short-wavelength light included in the second polarized light 710s having returned to the display device 710A may be emitted to the wavelength conversion member 715, as in the eighth embodiment. Also in this case, as in the eighth embodiment, the wavelength conversion member 715 can be expected to absorb the short-wavelength light of the second polarized light 710s and newly emit long-wavelength light.

The light-shielding member 760 is disposed between the display device 710A and the input element 121 of the imaging optical system 120. The shape of the light-shielding member 760 is, for example, a flat plate shape substantially parallel to the XY plane. The light-shielding member 760 is provided with an opening 761 penetrating through the light-shielding member 760 in the Z direction. The focal point F of the imaging optical system 120 is located within the opening 761.

Of the light emitted from the display device 710A, light passing through the focal point F and the vicinity thereof passes through the opening 761 of the light-shielding member 760 and enters the input element 121, and most of the other light is blocked by the light-shielding member 760. Of the second polarized light 710s reflected by the reflective polarizing element 750, light along the optical path, that is, light passing through the focal point F and the vicinity thereof passes through the opening 761 of the light-shielding member 760 and returns to the display device 710A. On the other hand, of the second polarized light 710s reflected by the reflective polarizing element 750, most of the light traveling toward the display device 710A without traveling along the optical path is blocked by the light-shielding member 760.

An effect of the present embodiment is described below.

The video display apparatus 70B according to the present embodiment further includes the reflective polarizing element 750. The reflective polarizing element 750 is disposed in a portion, where the plurality of principal rays L emitted from different positions in the display device 710A to pass through the first image IM1 are substantially parallel to each other, in the optical path from the display device 710A to the reflection unit 12, transmits the first polarized light 710p of the light emitted from the display device 710A, and reflects the second polarized light 710s of the light emitted from the display device 710A back to the display device 710A. Therefore, the luminance of the second image IM2 can be improved while increasing the proportion of the first polarized light 710p included in the light emitted from the video display apparatus 70B.

The light-shielding member 760 is provided between the display device 710A and the input element 121. The light-shielding member 760 is provided with the opening 761 through which the second polarized light 710s that returns to the display device 710A along the optical path passes. Therefore, while allowing the light along the optical path in the second polarized light 710s reflected by the reflective polarizing element 750 to return to the display device 710A, stray light not along the optical path in the second polarized light 710s reflected by the reflective polarizing element 750 can be inhibited from traveling toward the display device 710A. Thus, the quality of the first image IM1 and the second image IM2 can be improved. In addition, the light-shielding member 760 can inhibit stray light not along the optical path of the light emitted from the display device 710A from being reflected by the reflective polarizing element 750 and the optical elements of the imaging optical system 120, traveling toward the display device 710A, and being re-excited or scattered and reflected at an unexpected location.

The video display apparatus 70B need not be provided with the light-shielding member 760. The reflective polarizing element 740 described in the eighth embodiment may be further provided on the display device 710A of the video display apparatus 70B. In such a case, the second polarized light 710s not reflectable by the reflective polarizing element 740 on the display device 710A can be reflected by the reflective polarizing element 750. Therefore, the luminance of the second image IM2 can be improved while increasing the proportion of the first polarized light 710p included in the light emitted from the video display apparatus 70B. The configuration, operation, and effects of the present embodiment other than those described above are the same as those of the eighth embodiment.

### Modified Example of Ninth Embodiment

A modified example of the ninth embodiment is described below.

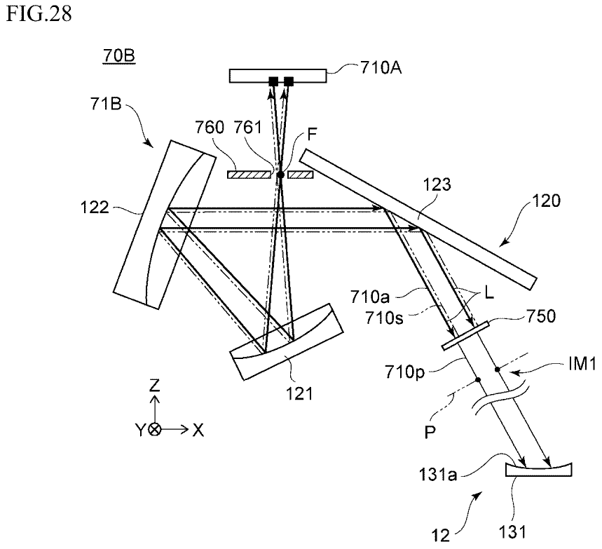

FIG. 28 is a side view illustrating a light source unit according to the present modified example.

Also in FIG. 28, only the light-shielding member 760 is illustrated in cross section.

As illustrated in FIG. 28, in the present modified example, the reflective polarizing element 750 is disposed between the output element 123 and the reflection unit 12. Although FIG. 28 illustrates an example in which the reflective polarizing element 750 is located between the output element 123 and the first image IM1, the reflective polarizing element 570 may be located between the first image IM1 and the reflection unit 12. The configuration, operation, and effects of the present modified example other than those described above are the same as those of the ninth embodiment.

Each of the aforementioned embodiments and the modified example thereof are examples embodying the present invention, and the present invention is not limited to these embodiments and modified example. For example, additions, deletions, or changes of some components or steps in each of the aforementioned embodiments and the modified example are also included in the present invention. Each of the aforementioned embodiments and the modified example can be implemented in combination with each other.

Embodiments of the present disclosure can be used, for example, in a head-up display.

1. Alight source unit comprising:
a display device configured to emit light that has a substantially Lambertian light distribution and to display a picture;
a first prism sheet on which the light emitted from the display device is incident; and
an imaging optical system that comprises an input element on which light emitted from the first prism sheet is incident and an output element on which light that has passed through the input element is incident, and configured such that light emitted from the output element forms a first image corresponding to the picture, wherein:
the imaging optical system has a substantially telecentric property on a side of the first image.

2. The light source unit according to claim 1, wherein:
the first prism sheet comprises a first surface on which the light emitted from the display device is incident, and a second surface configured to emit the light toward the input element,
on the first surface, a stripe-shaped first prism extending in a first direction is disposed, and
on the second surface, a stripe-shaped second prism extending in a second direction intersecting with the first direction is disposed.

3. The light source unit according to claim 2, wherein:
the display device comprises a plurality of pixels arranged along a third direction, and a fourth direction orthogonal to the third direction,
the first direction is inclined with respect to the third direction by 45°, and
the second direction is inclined with respect to the fourth direction by 45°.

4. The light source unit according to claim 1, further comprising:
a second prism sheet disposed between the first prism sheet and the input element, wherein:
on the first prism sheet, a stripe-shaped first prism extending in a first direction is disposed, and
on the second prism sheet, a stripe-shaped second prism extending in a second direction intersecting with the first direction is disposed.

5. The light source unit according to claim 4, wherein:
the display device comprises a plurality of pixels arranged along a third direction, and a fourth direction orthogonal to the third direction,
the first direction is inclined with respect to the third direction by 45°, and
the second direction is inclined with respect to the fourth direction by 45°.

6. The light source unit according to claim 1, wherein:
the light emitted from the display device has a light distribution pattern in which a luminous intensity of the light emitted from the display device in a direction at an angle θ with respect to an optical axis is approximated by cosⁿθ times a luminous intensity on the optical axis, and
n is a value greater than 0.

7. The light source unit according to claim 6, wherein n is 11 or less.

8. The light source unit according to claim 1, wherein the display device is an LED display comprising a plurality of LED elements.

9. The light source unit according to claim 8, wherein an LED element of the plurality of LED elements is configured to emit light that has a substantially Lambertian light distribution.

10. The light source unit according to claim 8, wherein the display device further comprises a wavelength conversion member disposed above an LED element of the LED elements and configured to receive the light emitted from the LED element.

11. The light source unit according to claim 1, wherein:
the imaging optical system comprises a bend portion comprising the input element, and a direction changing portion comprising the output element,
the bend portion is configured to bend a plurality of principal rays that are emitted from mutually different positions in the display device, intersect with each other before entering the input element, and reach the first image, such that the plurality of principal rays are substantially parallel to each other before and after the first image, and
the direction changing portion is configured to change a traveling direction of the plurality of principal rays that have passed through the bend portion such that the plurality of principal rays are directed to a formation position of the first image.

12. The light source unit according to claim 1, further comprising:
a light-shielding member that is disposed between the display device and the imaging optical system, comprises an opening through which a part of light traveling from the display device toward the imaging optical system passes, and is configured to block another part of the light traveling from the display device toward the imaging optical system.

13. A video display apparatus comprising:
the light source unit according to claim 1; and
a reflection unit that is spaced apart from the light source unit and configured to reflect light emitted from the imaging optical system,
wherein the first image is formed between the light source unit and the reflection unit.

14. The video display apparatus according to claim 13, further comprising:
a reflective polarizing element that is disposed on an optical path from the display device to the reflection unit, configured to transmit first polarized light of the light emitted from the display device, and configured to reflect second polarized light of the light emitted from the display device back to the display device.

15. An automobile comprising:
a vehicle; and
the video display apparatus according to claim 13, the video display apparatus being fixed to the vehicle.
